(19) United States
(12) Patent Application Publication
(10) Pub. No.: US 2025/0234603 A1
(43) Pub. Date: Jul. 17, 2025

(54) SEMICONDUCTOR STRUCTURE AND MANUFACTURING METHOD THEREOF

(71) Applicant: TAIWAN SEMICONDUCTOR MANUFACTURING COMPANY LTD., HSINCHU (TW)

(72) Inventors: TSUNG-HAN CHUANG, TAINAN CITY (TW); JUNG-HUNG CHANG, CHANGHUA COUNTY (TW); CHIA-CHENG TSAI, HSINCHU (TW); SHIH-CHENG CHEN, NEW TAIPEI CITY (TW); KUO-CHENG CHIANG, HSINCHU COUNTY (TW); CHIH-HAO WANG, HSINCHU COUNTY (TW)

(21) Appl. No.: 18/409,827

(22) Filed: Jan. 11, 2024

(51) Int. Cl. H01L 29/06; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 64/018

(57) ABSTRACT

A semiconductor structure includes a plurality of nanosheets, a gate structure, an S/D structure, a stepped structure, and a sidewall spacer. The plurality of nanosheets is disposed over a substrate, wherein the substrate extends along a first direction, and the nanosheets are arranged along a second direction substantially perpendicular to the first direction. The gate structure is disposed over the substrate, wherein the gate structure is disposed between and surrounding the nanosheets. The S/D structure is disposed adjacent to the gate structure and the plurality of nanosheets. The stepped structure is disposed below the S/D structure, wherein the stepped structure overlaps at least one of the nanosheets along the first direction. The sidewall spacer is disposed between the stepped structure and the at least one of the nanosheets. A method of manufacturing the semiconductor structure is also provided.

### BACKGROUND

The semiconductor integrated circuit industry has experienced rapid growth in the past several decades. Technological advances in semiconductor materials and design have produced increasingly compact and complex circuits. These material and design advances have been made possible as technologies related to processing and manufacturing have also undergone technical advances. As the semiconductor industry has progressed into advanced technology process nodes in pursuit of smaller product scales and multiple functions, various approaches have been studied and an obstacle to integrating devices with different functions has been encountered.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a schematic top-view diagram of a semiconductor structure in accordance with some embodiments of the present disclosure.

FIGS. 2A, 2B, 2C, 2D, 2E, 2F, 2G and 2H are schematic cross-sectional diagrams of the semiconductor structure along lines A-A′, B-B′, C-C′, D-D′, E-E′, F-F′, G-G′ and H-H′ respectively in FIG. 1 in accordance with some embodiments of the present disclosure.

FIGS. 3A, 3B, 4A, 4B, 5A, 5B, 6A, 6B, 7A, 7B, 8A, 8B, 9A, 9B, 10A, 10B, 11A, 11B, 12A, 12B, 13A, 13B, 13C, 13D, 14A, 14B, 14C and 14D are schematic cross-sectional diagrams along different cut lines and at different stages of a manufacturing method of a semiconductor structure in accordance with some embodiments of the present disclosure.

FIGS. 15A, 15B, 15C, 15D, 15E, 15F, 15G and 15H are schematic cross-sectional diagrams of the semiconductor structure along the lines A-A′, B-B′, C-C′, D-D′, E-E′, F-F′, G-G′ and H-H′ respectively in FIG. 1 in accordance with other embodiments of the present disclosure.

FIGS. 16A, 16B, 17A, 17B, 17C, 17D, 18A, 18B, 18C, 18D, 19A, 19B, 19C, 19D, 20A, 20B, 20C, 20D, 21A, 21B, 22A, 22B, 22C, 22D, 23A, 23B, 23C and 23D are schematic cross-sectional diagrams along different cut lines and at different stages of a manufacturing method of a semiconductor structure in accordance with some embodiments of the present disclosure.

FIG. 24 is a flow diagram of a method for manufacturing a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context. In addition, the term “source/drain region” or “source/drain regions” may refer to a source or a drain, individually or collectively dependent upon the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of time, temperatures, operating conditions, ratios of amounts, and the likes thereof disclosed herein, should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

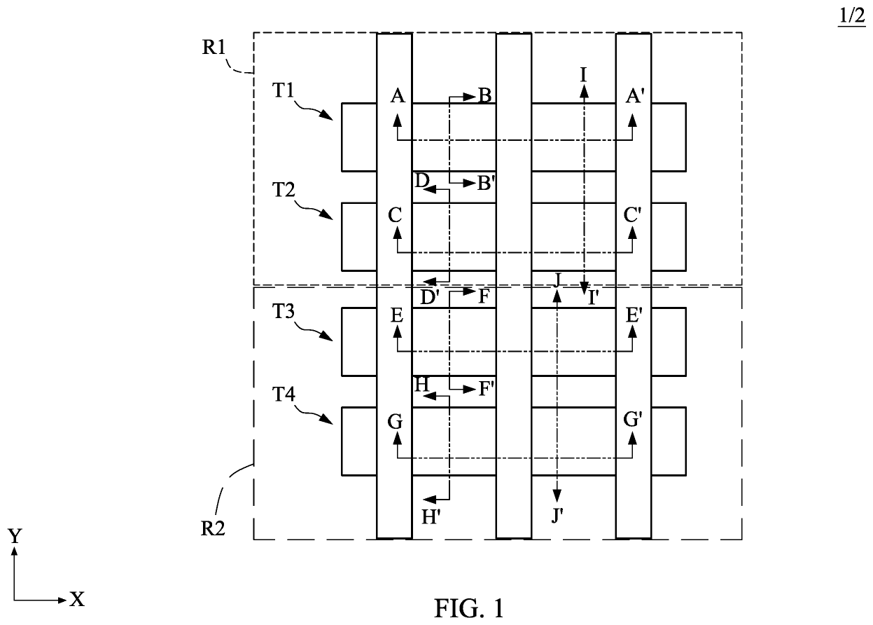

FIG. 1 is a schematic top-view diagram of a semiconductor structure 1 in accordance with some embodiments of the present disclosure. The semiconductor structure 1 includes a first region R1, which is designed for a performance advantage in power, and a second region R2, which is designed for a performance advantage in speed. The first region R1 may include multiple transistors T1 and T2, and the second region R2 may include multiple transistors T3 and T4. The transistors T1 and T2 can have different types of conductivities. For example, the transistor T1 can be an N-type transistor and the transistor T2 can be a P-type transistor. Similarly, the transistors T3 and T4 can have different types of conductivities. For example, the transistor T3 can be a P-type transistor and the transistor T4 can be an N-type transistor. The transistors T1, T2, T3 and T4 can have different types or generations of devices. The transistors T1, T2, T3 and T4 can include one or more types of transistors, such as a planar transistor, a multi-gate transistor, a gate-all-around field-effect transistor (GAAFET), a fin field-effect transistor (FinFET), a vertical transistor, a nanosheet transistor, a nanowire transistor, a bipolar junction transistor (BJT), a high-electron-mobility transistor (HEMT or HEM FET), a selector (including Ovonic threshold switching or tunneling types), or a combination thereof.

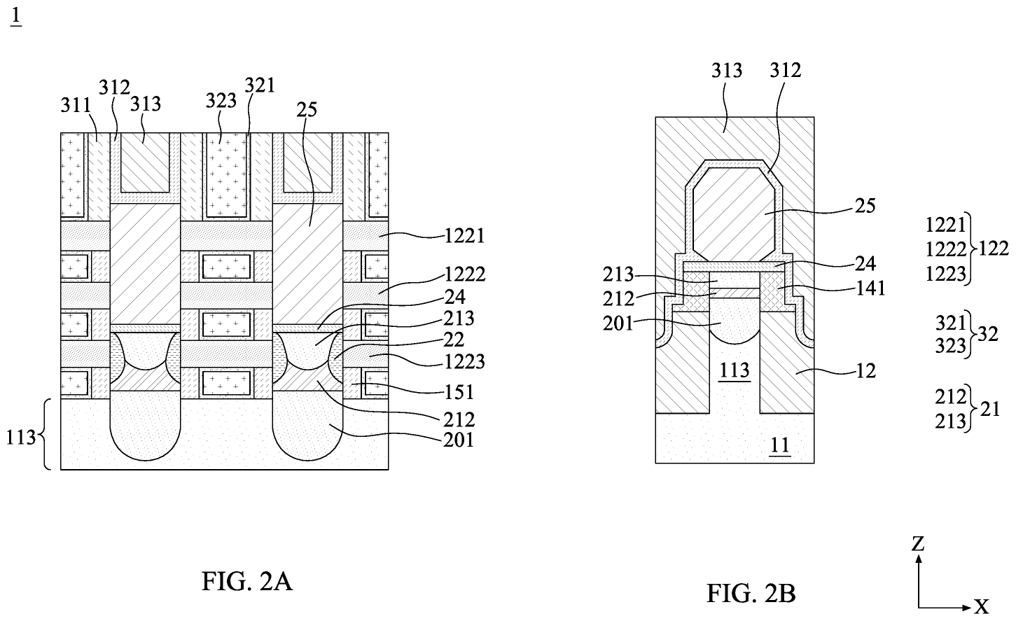

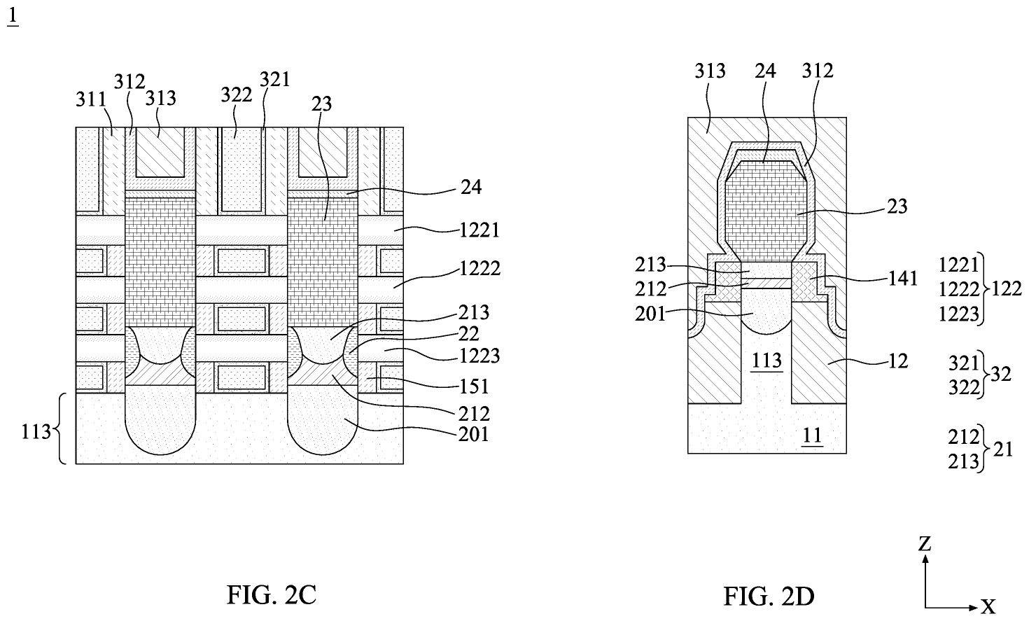

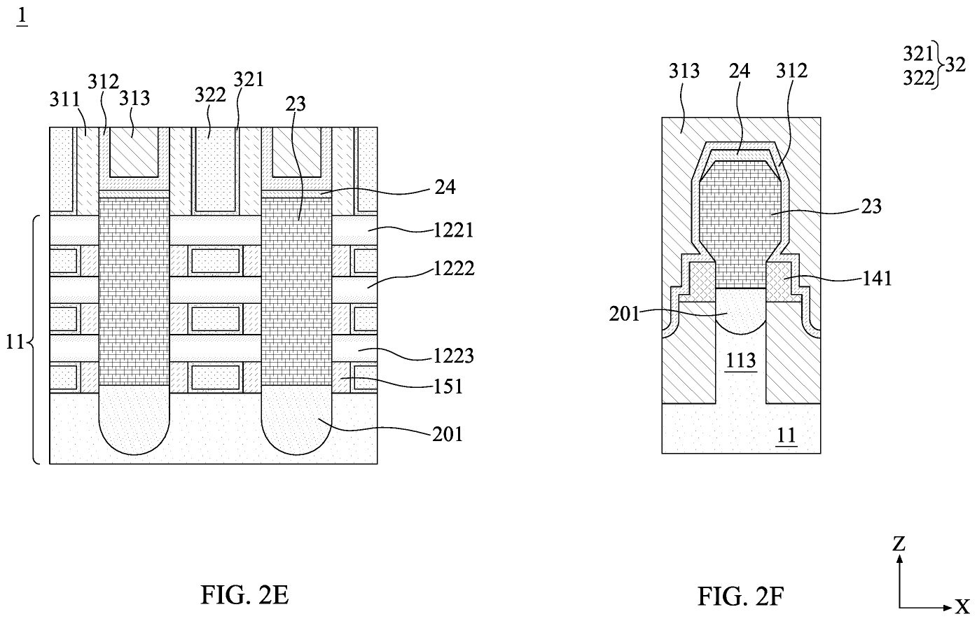

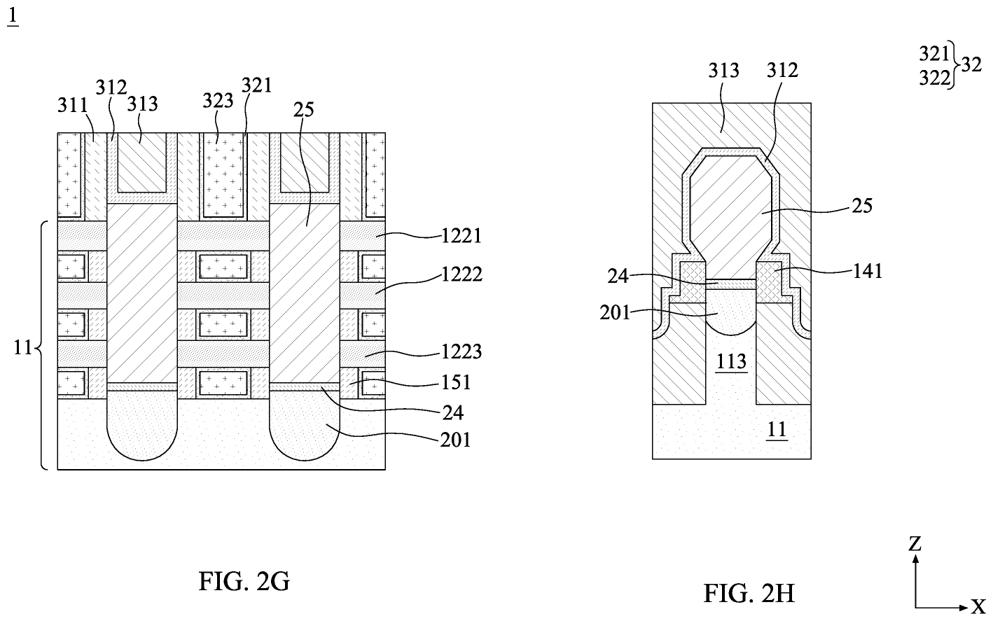

FIGS. 2A, 2B, 2C, 2D, 2E, 2F, 2G and 2H are schematic cross-sectional diagrams of the semiconductor structure 1 along lines A-A′, B-B′, C-C′, D-D′, E-E′, F-F′, G-G′ and H-H′ respectively in FIG. 1 in accordance with some embodiments of the present disclosure. The transistors T1, T2, T3 and T4 shown in the figures are GAAFETs (e.g., nanosheet transistors) for exemplary illustration. However, the present disclosure is not limited thereto.

As shown in FIGS. 1, 2A, 2B, 2C, 2D, 2E, 2F, 2G and 2H, each of the transistors T1, T2, T3 and T4 includes a plurality of nanosheets 122. For example, each of the transistors T1, T2, T3 and T4 includes three nanosheets 1221, 1222 and 1223. In some embodiments, the nanosheets 1221 and 1222 of the transistors T1 and T2 in the first region R1 are functional nanosheets (or functional channels). In some embodiments, the nanosheets 1223 of the transistors T1 and T2 in the first region R1 are dummy nanosheets (or dummy channels). Each of the transistors T1 and T2 in the first region R1 has fewer functional nanosheets than either of the transistors T3 and T4 in the second region R2. A channel length can be defined between a distance of source and drain structures (e.g., N-type source/drain structures 23 of the transistor T2 or T3 or P-type source/drain structures 25 of the transistor T1 or T4). In some embodiments, channel lengths of the transistors T1, T2, T3 and T4 are substantially equal. Different numbers of functional nanosheets of transistors in different regions can be integrated, thereby providing different performance advantages in different regions of the semiconductor structure 1 in accordance with different applications.

The transistors T1 and T2 may have similar structures but with different types of conductivities. The transistors T1 and T2 are formed over a substrate 11, including a plurality of fin structures 113. The substrate 11 may include a bulk semiconductor material, such as silicon, or other semiconductor materials, such as silicon germanium, silicon carbide, gallium arsenide, or the like. The substrate 11 may be of a first conductivity type, e.g., a P-type semiconductive substrate (acceptor type), or a second conductivity type, e.g., an N-type semiconductive substrate (donor type).

An isolation 12 is disposed over the substrate 11 and between the fin structures 113. In some embodiments, the transistor T1 includes the plurality of nanosheets 122 disposed over the fin structure 113 of the substrate 11. In some embodiments, the substrate 11 extends along a first direction (e.g., an X direction), and the nanosheets 122 are arranged along a second direction (e.g., a Z direction) substantially perpendicular to the first direction. In some embodiments, the transistor T1 includes a gate structure 32 disposed over the substrate 11. In some embodiments, the gate structure 32 includes a high-k dielectric layer 321 and a gate electrode 322 surrounded by the high-k dielectric layer 321. In some embodiments, the transistor T1 includes a pair of source/drain (S/D) structures 25, disposed adjacent to and on two opposite sides of the gate structure 32. In some embodiments, the S/D structures 25 are disposed on two opposite sides of the nanosheets 122.

In order to control a number of functional nanosheets, the transistor T1 further includes a stepped structure 21 disposed below each of the S/D structures 25. In some embodiments, a spacer layer 141 (including a pair of sidewall spacers) is disposed over the isolation 12 and on two opposite sides of the stepped structure 21. In some embodiments, a height of the stepped structure 21 is defined by a height of the spacer layer 141. In some embodiments, a top surface of the stepped structure 21 is below or aligned with a top surface of the spacer layer 141. The stepped structure 21 overlaps at least one of the nanosheets 122 along the first direction. For instance, the stepped structure 21 overlaps the nanosheet 1223 along the X direction. In some embodiments, the stepped structure 21 overlaps a sidewall of the nanosheet 1223. The stepped structure 21 can include different portions with different semiconductor materials. In some embodiments, the different portions of the stepped structure 21 have different concentrations of an element selected from III-V groups. In some embodiments, the stepped structure 21 includes an upper portion 213 and a lower portion 212 disposed below the upper portion 213. In some embodiments, the upper portion 213 includes polysilicon, and the lower portion 212 includes silicon germanium. In some embodiments, the lower portion 212 has a germanium concentration in a range of 20% to 35%.

The S/D structures 25 are disposed on top of the stepped structure 21, and therefore the S/D structures 25 horizontally overlap the nanosheets 1221 and 1222 and are separated from the nanosheet 1223 by the stepped structure 21. The nanosheets 1221 and 1222 are functional channels of the transistors T1, and the nanosheet 1223 is a dummy channel of the transistor T1. In some embodiments, the transistor T1 further includes an epitaxial portion 201 disposed between the fin structure 113 and the stepped structure 21. The epitaxial portion 201 can be a lowest portion of an epitaxial structure formed at a beginning of an epitaxial growth. In some embodiments, the epitaxial portion 201 is referred to as an LO layer.

For a purpose of preventing current leakage between the S/D structure 25 and the nanosheet 1223, the transistor T1 may further include a sidewall spacer 22, disposed between the stepped structure 21 and the nanosheet 1223. The sidewall spacer 22 may include a dielectric material, such as oxide, nitride, oxynitride, or a combination thereof. In some embodiments, the sidewall spacer 22 contacts a sidewall of the stepped structure 21. In some embodiments, the sidewall spacer 22 contacts the upper portion 213 and the lower portion 212. In some embodiments, the sidewall spacer 22 contacts the sidewall of the nanosheet 1223. A configuration of the sidewall spacer 22 is defined by the stepped structure 21 and adjacent nanosheets 122. In some embodiments as shown in FIG. 2A, the sidewall spacer 22 of the transistor T1 has a curved sidewall facing the stepped structure 21. In some embodiments, a width of the sidewall spacer 22 measured along the first direction is in a range of 1 to 4 nanometers (nm). In some embodiments, a height of the sidewall spacer 22 measured along the second direction is in a range of 10 to 20 nm.

The transistor T1 may further include a dielectric layer 24, disposed between the stepped structure 21 and the S/D structure 25. In some embodiments, the S/D structure 25 is separated from the stepped structure 21 by the dielectric layer 24. The dielectric layer 24 can prevent current leakage between the S/D structure 25 and the nanosheet 1223. The presence of the dielectric layer 24 may not affect a strain of the S/D structure 25 when the S/D structure 25 is an N-type epitaxial structure. In some embodiments, a thickness of the dielectric layer 24 is in a range of 3 to 5 nm.

The semiconductor structure 1 can further include a plurality of dielectric layers (e.g., 311, 312 and 313) disposed over the substrate 11 and between adjacent gate structures 32. In some embodiments, the dielectric layers 311 and 312 are collectively referred to as an isolation structure 31. In some embodiments, the dielectric layer 313 is referred to as a spacer of the gate structure 32. In some embodiments, the dielectric layer 312 is disposed over and conformal to the S/D structures 25.

As shown in FIGS. 2C and 2D, the transistor T2 can have a structure similar to that of the transistor T1 as shown in FIGS. 2A and 2B but with the dielectric layer 24 being on top of an S/D structure 23 of the transistor T2. A type of conductivity of the transistor T2 can be different from that of the transistor T1, and thus, the transistor T2 includes the S/D structure 23 having a type of conductivity different from that of the S/D structure 25. A material of a gate electrode 322 of a gate structure 32 of the transistor T2 can be different from that of the gate electrode 323 of the gate structure 32 of the transistor T1. The presence of the dielectric layer 24 between the S/D structure 23 and the stepped structure 21 may affect strain of the S/D structure 23 when the S/D structure 23 is a P-type epitaxial structure. In some embodiments, the dielectric layer 24 is disposed over the S/D structure 23. In some embodiments, the S/D structure 23 contacts the stepped structure 21 (e.g., the upper portion 213 of the stepped structure 21).

The transistors T3 and T4 in the second region R2 are similar to the transistors T2 and T1 in the first region R1 but without the stepped structures 21. More specifically, the transistor T3 is similar to the transistor T2 but without the stepped structure 21 shown in FIGS. 2C and 2D, and the transistor T4 is similar to the transistor T1 but without the stepped structure 21 shown in FIGS. 2A and 2B. In some embodiments, the transistors T2 and T3 have a same type of conductivity. In some embodiments, the transistors T1 and T4 have a same type of conductivity, which is different from that of the transistors T2 and T3. In some embodiments as shown in FIG. 2E, without the stepped structure 21, an S/D structure 23 overlaps all nanosheets 1221, 1222 and 1223 along the first direction, wherein the nanosheets 1221, 1222 and 1223 are all functional nanosheets of the transistor T3. In some embodiments, the S/D structure 23 contacts the epitaxial portion 201. In some embodiments as shown in FIG. 2F, a lower portion of the S/D structure 23 is surrounded by the spacer layer 141. In some embodiments, a bottom of the S/D structure 23 is below a top surface of the spacer layer 141.

Similarly, in some embodiments as shown in FIG. 2G, without the stepped structure 21, an S/D structure 25 overlaps all nanosheets 1221, 1222 and 1223 along the first direction, wherein the nanosheets 1221, 1222 and 1223 are all functional nanosheets of the transistor T4. In some embodiments, the dielectric layer 24 is disposed between the epitaxial portion 201 and the S/D structure 25. In some embodiments, the dielectric layer 24 contacts the epitaxial portion 201 and the S/D structure 25. In some embodiments as shown in FIG. 2H, the dielectric layer 24 is disposed between different portions (i.e., a pair of sidewall spacers) of the spacer layer 141. In some embodiments, a lower portion of the S/D structure 25 is surrounded by the spacer layer 141. In some embodiments, a bottom of the S/D structure 25 is below a top surface of the spacer layer 141.

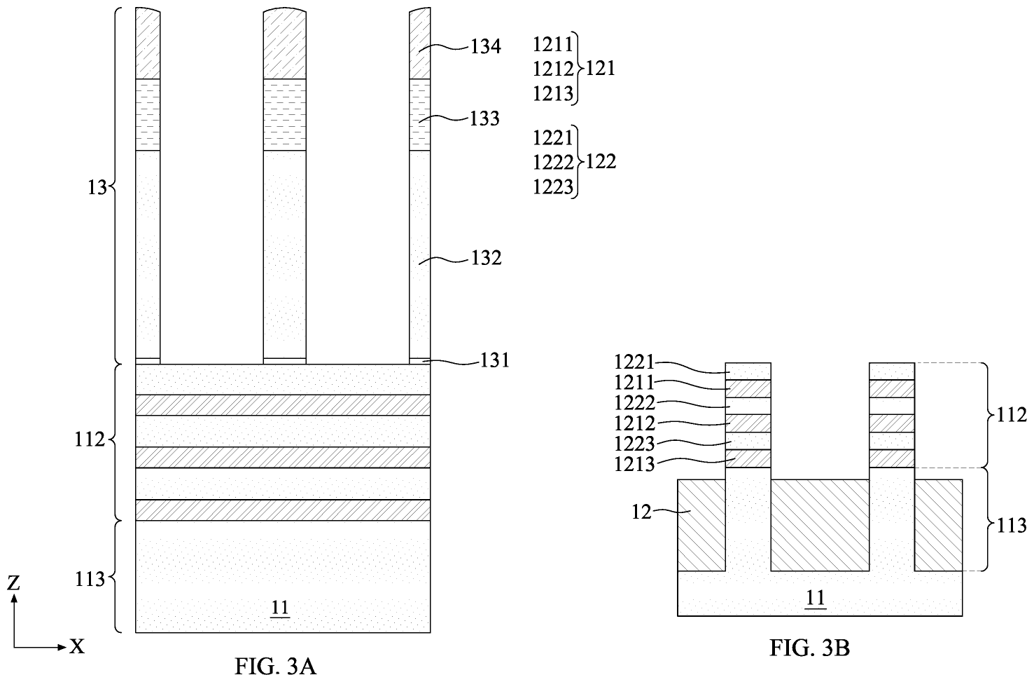

FIGS. 3A, 3B, 4A, 4B, 5A, 5B, 6A, 6B, 7A, 7B, 8A, 8B, 9A, 9B, 10A, 10B, 11A, 11B, 12A, 12B, 13A, 13B, 13C, 13D, 14A, 14B, 14C and 14D are schematic cross-sectional diagrams at different stages of a manufacturing method of the semiconductor structure 1 in accordance with some embodiments of the present disclosure. FIGS. 3A, 4A, 5A, 6A, 7A, 8A, 10A, 11A and 12A are schematic cross-sectional diagrams along the line A-A′ or B-B′ at different stages of the manufacturing method of the semiconductor structure 1. FIGS. 3B, 4B, 5B, 6B, 7B, 8B, 10B, 11B and 12B are schematic cross-sectional diagrams along a line I-I′ shown in FIG. 1 at different stages of a manufacturing method of the semiconductor structure 1 in accordance with some embodiments of the present disclosure.

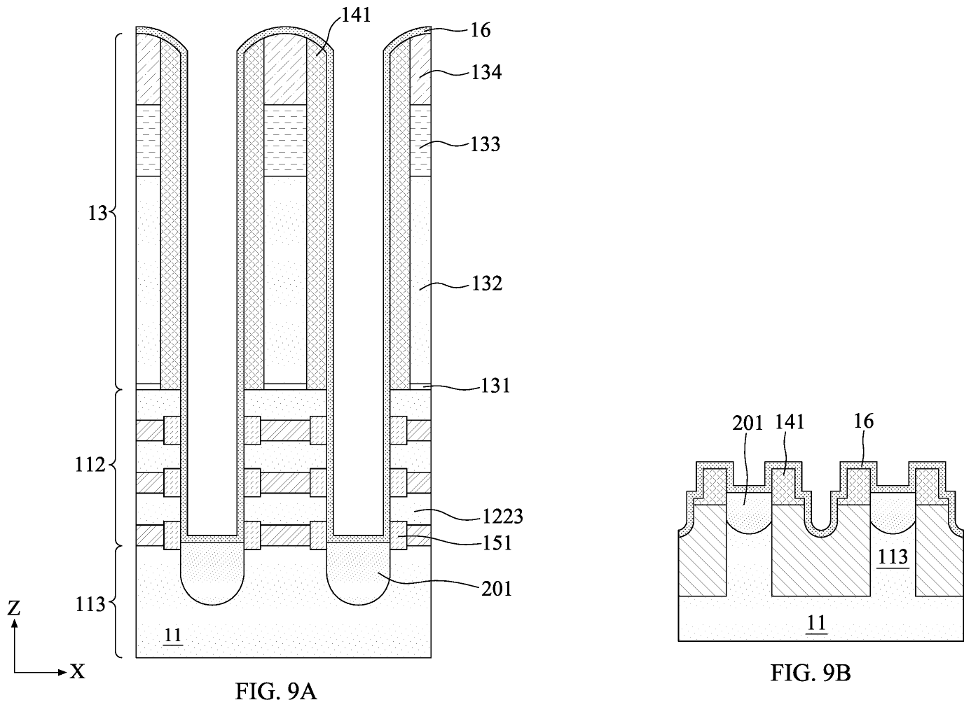

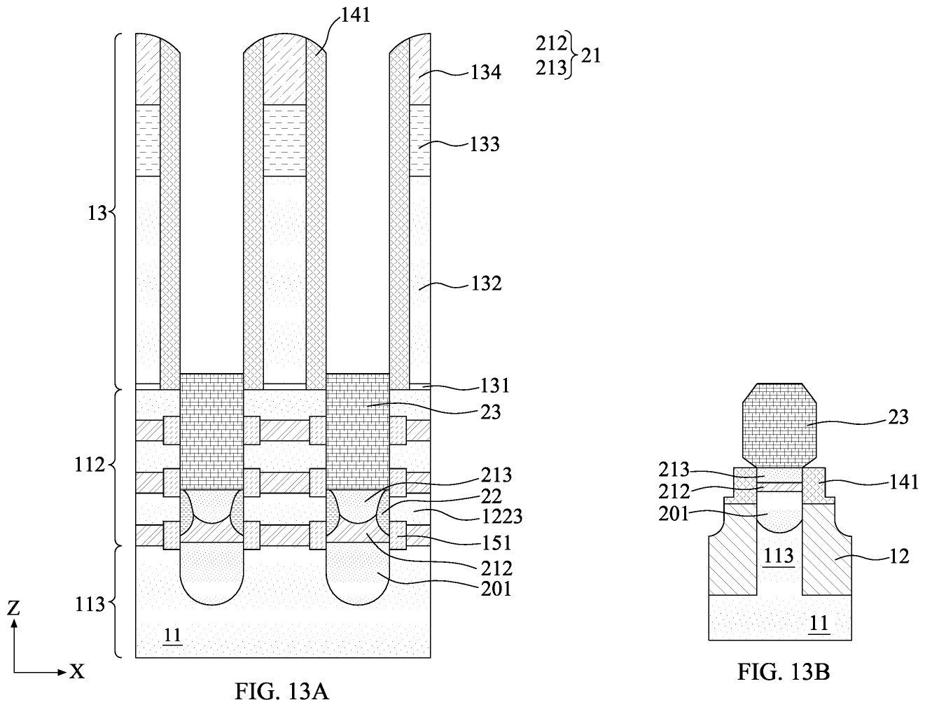

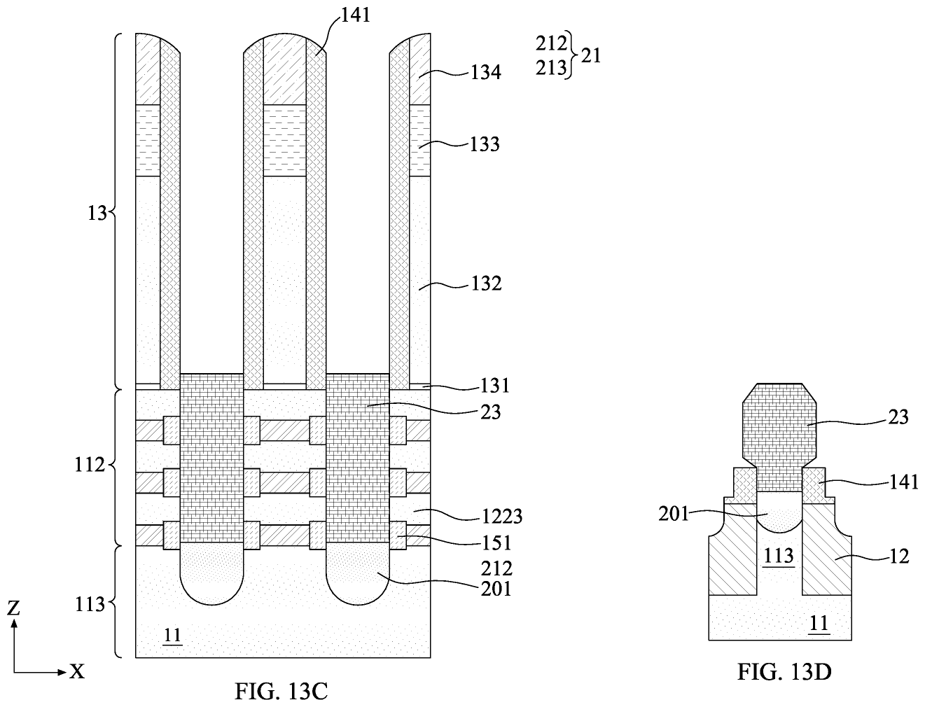

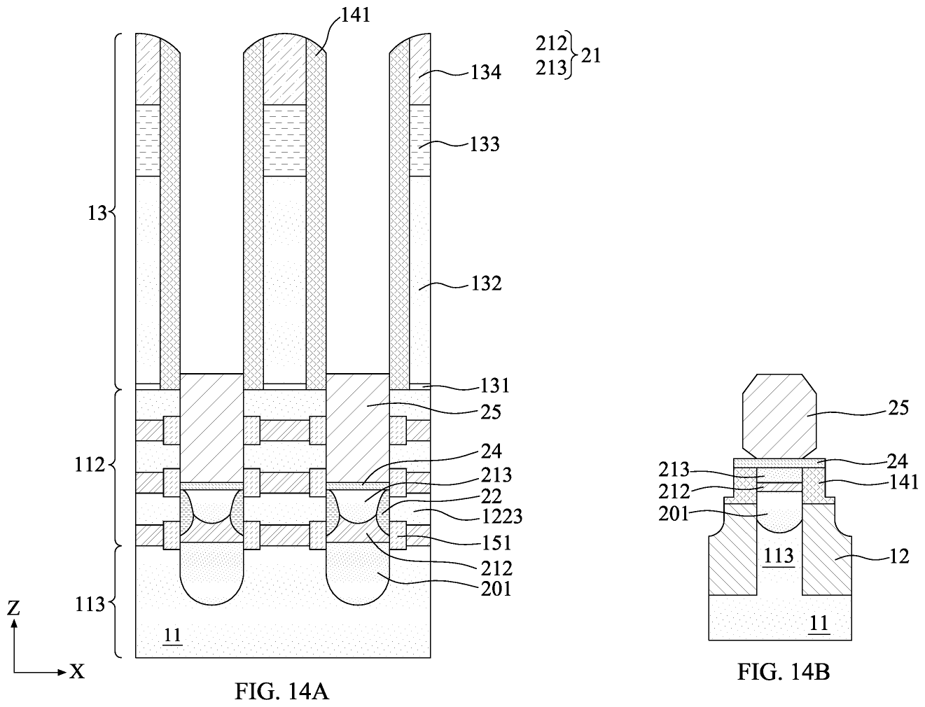

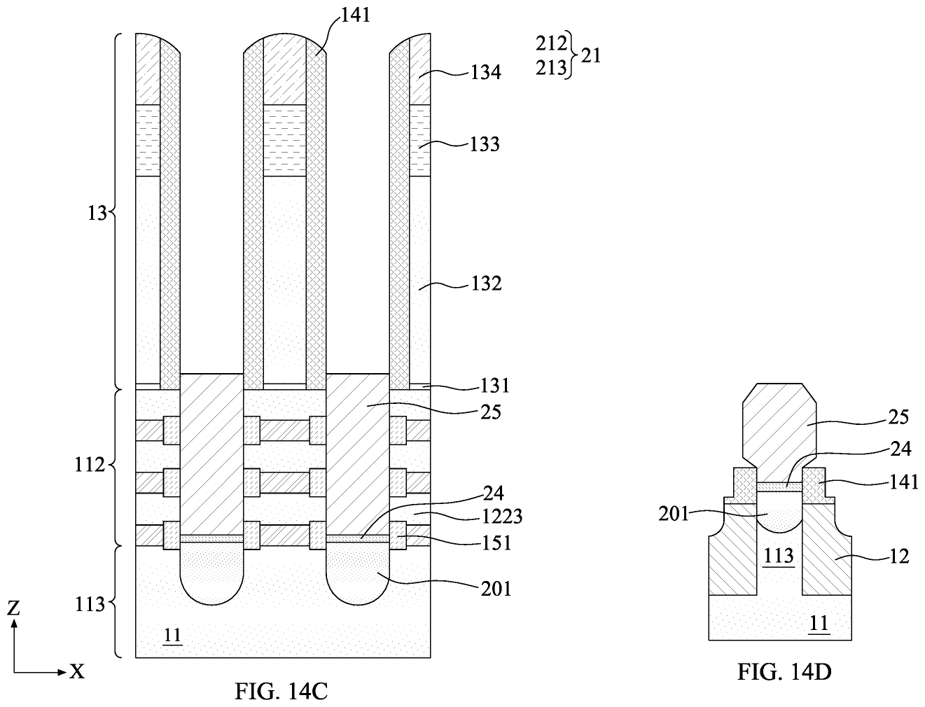

FIGS. 9A and 9B are schematic cross-sectional diagrams along the lines E-E′ and J-J′ respectively shown in FIG. 1 at a stage of a manufacturing method of the semiconductor structure 1 in accordance with some embodiments of the present disclosure. FIGS. 13A, 13B, 13C and 13D are schematic cross-sectional diagrams along the lines C-C′, D-D′, E-E′ and F-F′ respectively shown in FIG. 1 at a stage of a manufacturing method of the semiconductor structure 1 in accordance with some embodiments of the present disclosure. FIGS. 14A, 14B, 14C and 14D are schematic cross-sectional diagrams along the lines A-A′, B-B′, G-G′ and H-H′ respectively shown in FIG. 1 at a stage of a manufacturing method of the semiconductor structure 1 in accordance with some embodiments of the present disclosure.

Referring to FIGS. 3A and 3B, a substrate 11 including a plurality of fin structures 113 is received or formed. The fin structures 113 extend along the first direction and are substantially parallel to one another. A plurality of first semiconductor layers 121 and a plurality of second semiconductor layers 122 are alternately formed over the substrate 11 along the second direction. In some embodiments, the first semiconductor layers 121 and the second semiconductor layers 122 are alternately arranged over each of the fin structures 113. FIG. 3B shows three (e.g., 1211, 1212 and 1213) of the first semiconductor layers 121 and three (e.g., 1221, 1222 and 1223) of the second semiconductor layers 122 for a purpose of illustration. A number of the first semiconductor layers 121 and a number of the second semiconductor layers 122 can be adjusted according to different applications. The number of the second semiconductor layers 122 depends on a number nanosheets to be formed, and the number of the first semiconductor layers 121 corresponds to the number of the second semiconductor layers 122.

In some embodiments, depositions of two different semiconductor materials are alternately performed on the substrate 11, and one or more etching operations are performed on the two different semiconductor materials and the substrate 11, thereby forming the first semiconductor layers 121 and the second semiconductor layers 122 on the fin structures 113 as shown in FIGS. 3A and 3B. In some embodiments, a bottom-most first semiconductor layer 1213 contacts the fin structures 113. In some embodiments, the first semiconductor layer 121 includes silicon germanium, and the second semiconductor layer 122 includes polysilicon. For a purpose of illustration, a group of the first semiconductor layers 121 and the second semiconductor layers 122 stacked on one fin structure 13 is referred to as a strip structure 112.

An isolation 12 may be formed over the substrate 11 and between the fin structures 113. In some embodiments, a top surface of the isolation 12 is below a top surface of the substrate 11. In some embodiments, the top surface of the isolation 12 is below a top surface of the fin structures 113. In some embodiments, the top surface of the isolation 12 is below an interface between the strip structure 112 and the fin structures 113.

A plurality of dummy gate structures 13 are formed over the fin structures 113. In some embodiments, the dummy gate structures 13 are substantially parallel to one another, and arranged along the first direction. In some embodiments, each of the dummy gate structures 13 extends along a third direction (e.g., a Y direction shown in FIG. 1). In some embodiments, each of the dummy gate structures 13 extends across the fin structures 113. The dummy gate structures 13 may include a dielectric layer 131 disposed on the substrate 11 and the fin structures 113, a polysilicon layer 132 disposed over the dielectric layer 131, a cap layer 133 disposed over the polysilicon layer 132, and a hard layer 134 disposed over the cap layer 133. The dielectric layer 131, the cap layer 133, and the hard layer 134 can include same or different dielectric materials, such as oxide, nitride, oxynitride, a high-k dielectric material, a low-k dielectric material, or a combination thereof. In some embodiments, the dielectric layer 131 includes silicon oxide. In some embodiments, the cap layer 133 includes silicon nitride. In some embodiments, the hard layer 134 includes silicon oxide, silicon oxynitride, or a combination thereof.

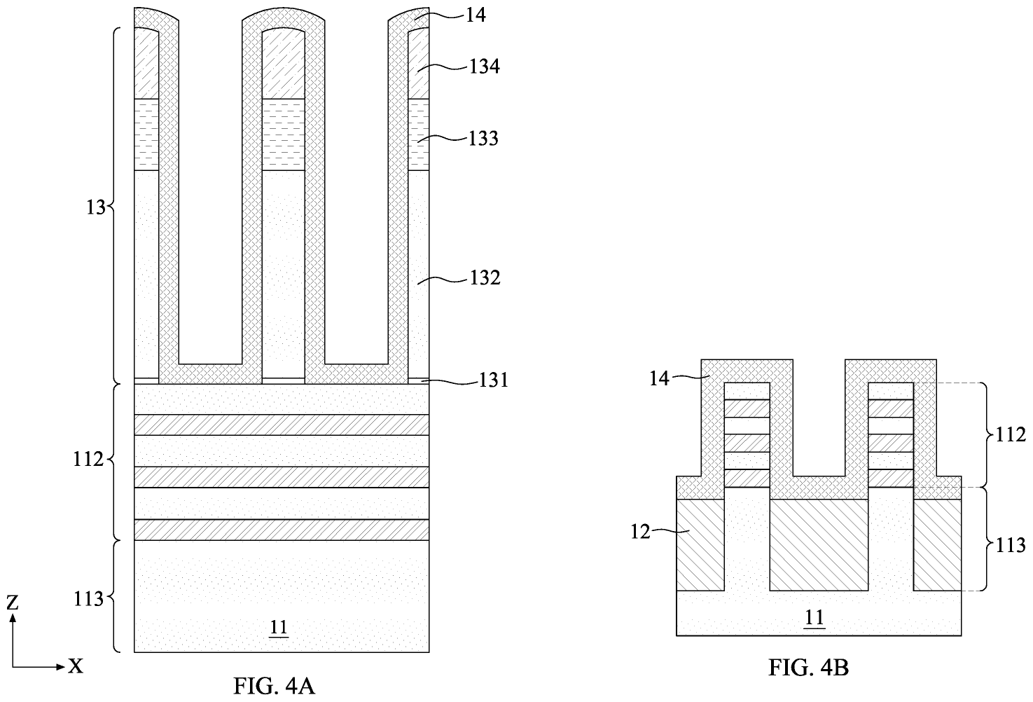

Referring to FIGS. 4A and 4B, a dielectric layer 14 is formed over the substrate 11. The dielectric layer 14 may be conformal to a profile of the fin structures 113, the dummy gate structure 13 and the substrate 11. In some embodiments, a conformal deposition is performed to form the dielectric layer 14. The dielectric layer 14 may be formed using a suitable process, such as atomic layer deposition (ALD), chemical vapor deposition (CVD), physical vapor deposition (PVD), plasma-enhanced PVD (PEPVD), plasma-enhanced ALD (PEALD), or a combination thereof.

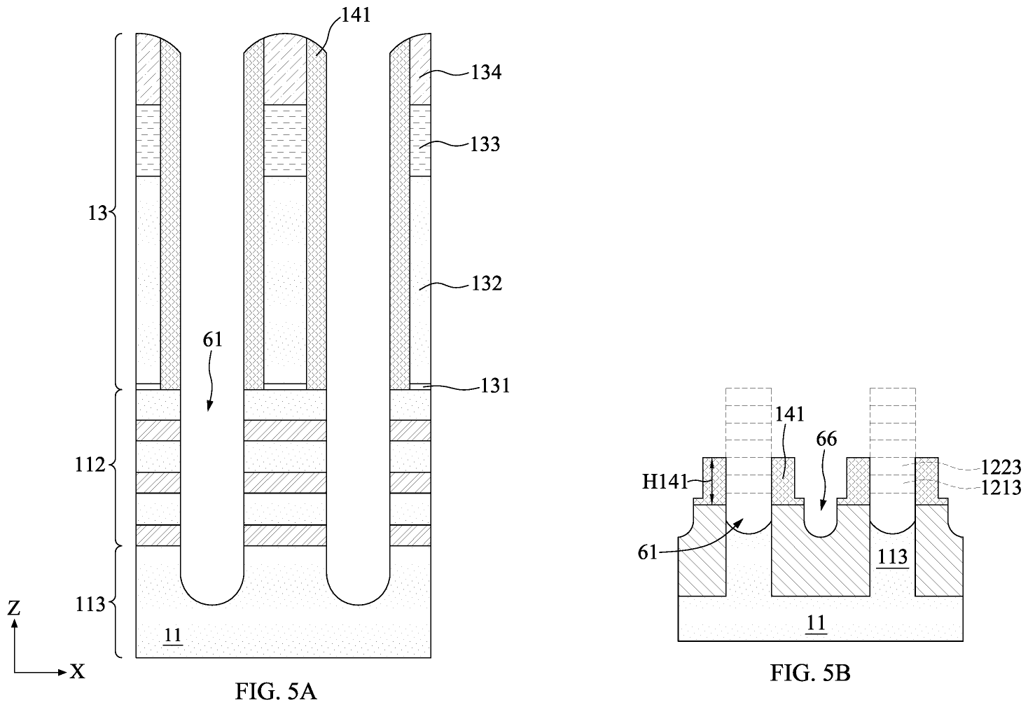

Referring to FIGS. 5A and 5B, a spacer etching operation is performed to form a spacer layer 141 on two opposite sides of each of the dummy gate structures 13, and a plurality of trenches 61 are formed using the spacer layer 141 and the dummy gate structures 13 as a mask. In some embodiments as shown in FIG. 5B, portions of the isolation 12 between portions of the spacer layer 141 are removed. In some embodiments, a plurality of trenches 66 are formed in the isolations 12 between adjacent fin structures 113. In some embodiments, an etching operation is performed on the dielectric layer 14 to remove horizontal portions of the dielectric layer 14, thereby forming the spacer layer 141. In some embodiments, a dielectric material of the dielectric layer 14 is different from that of the hard layer 134. In some embodiments, the dielectric material of the dielectric layer 14 and that of the hard layer 134 have a high etching selectivity ratio with respect to an etchant of the etching operation to form the spacer layer 141 (including pairs of sidewall spacers formed by the etching operation). In some embodiments, the etchant of the spacer etching operation is selective to the dielectric material of the dielectric layer 14 with respect to the hard mask 134. In some embodiments, the spacer etching operation is a time-mode etching operation, and is controlled to further remove some of vertical portions of the dielectric layer 14 lining sidewalls of the strip structures 112. In some embodiments, the trenches 66 are formed concurrently with the formation of the spacer layer 141. In some embodiments, the trenches 66 are formed by the spacer etching operation. As shown in FIG. 5B, the spacer layer 141 is further disposed on sidewalls of a lower portion of each of the strip structures 112. In some embodiments, portions of the strip structures 112 are removed in the subsequent formation of the trench 61, and boundaries of the removed portions of the strip structures 112 are shown with dotted lines in FIG. 5B for a purpose of illustration. In some embodiments, as shown in FIG. 5B, the spacer layer 141 on the isolation 12 has a height H141, wherein the height H141 is controlled so that a top surface of the spacer layer 141 is substantially aligned with or above a top surface of a bottom-most second semiconductor layer 1223.

The trenches 61 may be formed by one or more etching operations performed on the first semiconductor layers 121 and the second semiconductor layers 122. In some embodiments, the trenches 61 separate each strip structure 112 into portions. For a purpose of illustration, the strip structure 112 is referred to as a stack structure 112 after the formation of the trenches 61. In some embodiments, portions of the fin structure 113 below removed portions of the strip structure 112 are removed. In some embodiments, a bottom of the trench 61 is below a top surface of the isolation 12.

In some embodiments, a dry etching operation is performed. In some embodiments, an etchant of the dry etching operation has a low etching selectivity ratio between dielectric materials and semiconductor materials. In some embodiments, the trenches 61 and 66 and the spacer layer 141 are concurrently formed by the dry etching operation. In some embodiments, the dry etching operation is a time-mode etching operation. In some embodiments, a bottom of the trenches 66 is substantially leveled with a bottom of the trenches 61.

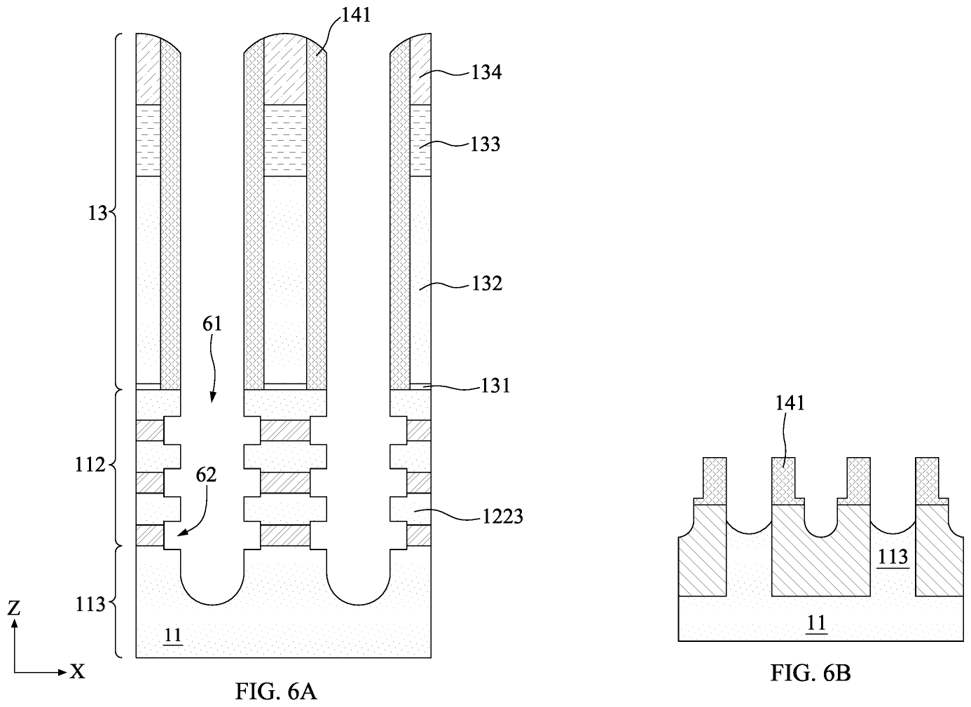

Referring to FIGS. 6A and 6B, lateral portions of the first semiconductor layers 121 are removed. In some embodiments, an etching operation is performed on exposed sidewalls of the first semiconductor layers 121, and a plurality of recesses 62 are formed. In some embodiments, the etching operation includes an isotropic etching operation. In some embodiments, the etching operation includes a wet etching operation.

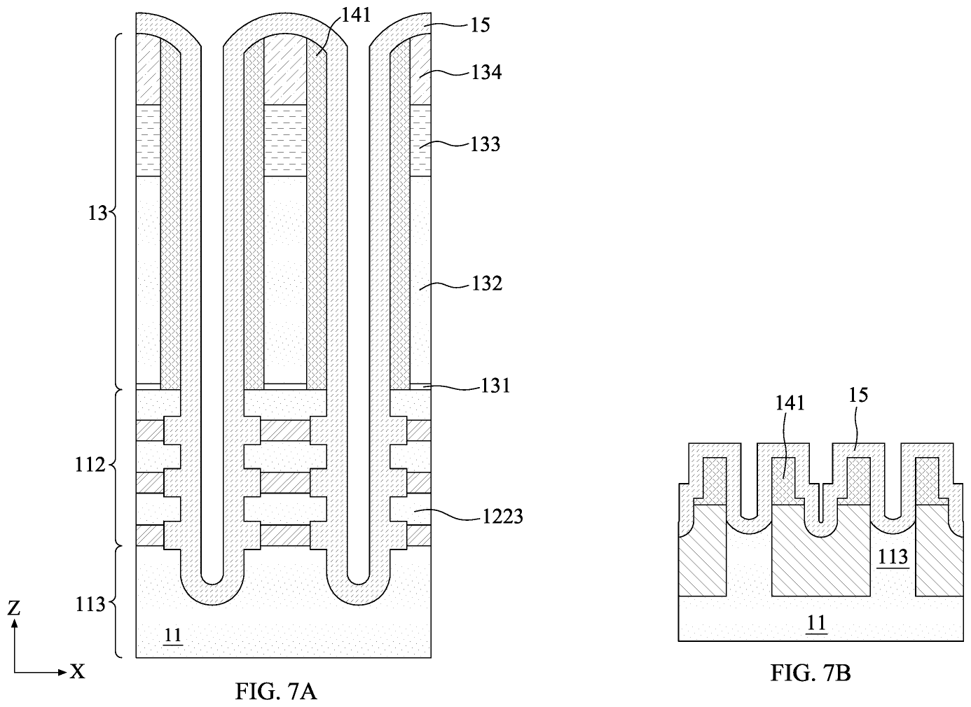

Referring to FIGS. 7A and 7B, a dielectric layer 15 is formed over the substrate 11, the fin structures 113, the dummy gate structures 13, and the stack structures 112. The dielectric layer 15 may be conformal to a profile of the substrate 11, the fin structures 113, the dummy gate structures 13, the isolations 12, and the stack structures 112. The formation of the dielectric layer 15 can be similar to the formation of the dielectric layer 14, and repeated description is omitted herein. In some embodiments, a dielectric material of the dielectric layer 15 is different from that of the dielectric layer 14 for a purpose of a desired etching selectivity of an etching operation performed in subsequent processing. The dielectric layer 15 fills the recesses 62 as shown in FIG. 7A.

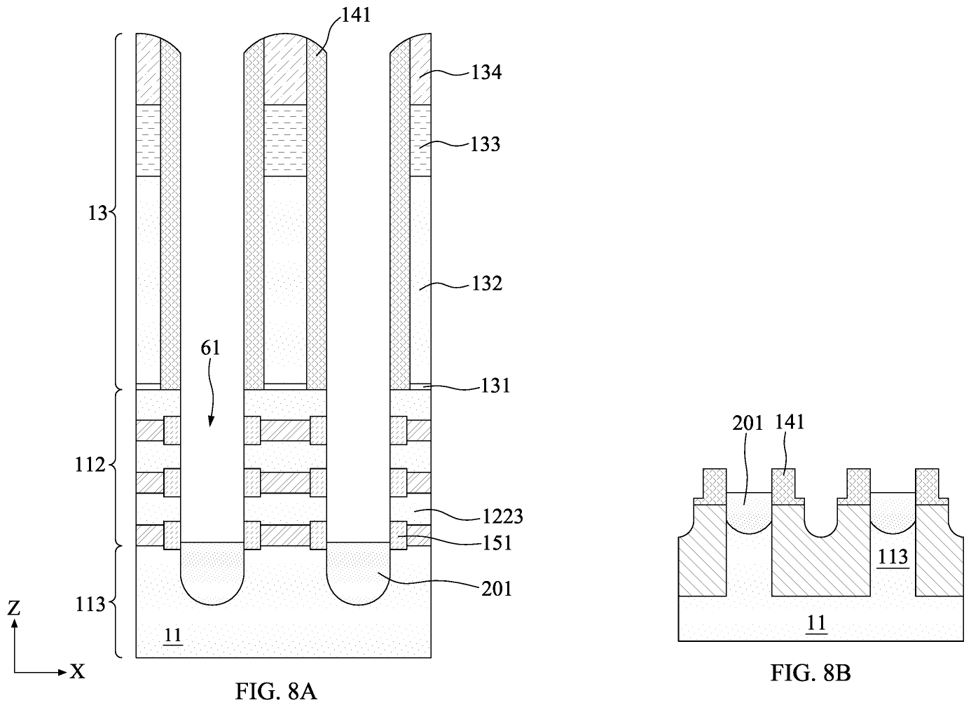

Referring to FIGS. 8A and 8B, an etching operation is performed to remove portions of the dielectric layer 15 outside the recesses 62 shown in FIG. 7A, and a plurality of inner spacers 151 are thereby formed. An epitaxial growth is then performed to form an epitaxial portion 201 at a bottom of each of the trenches 61. In some embodiments, during the epitaxial growth, the epitaxial portion 201 grows along the fin structure 113 in the trench 61, such that the epitaxial portion 201 defines a bottom surface of the trench 61. In some embodiments, the epitaxial portion 201 has a bottom-up growing direction. The epitaxial growth is controlled to limit crystal growth on sidewalls of the stack structures 112. In some embodiments, an etching operation is performed to ensure no undesired crystal grows or remains on the sidewalls of the stack structures 112. In some embodiments, a top surface of the epitaxial portion 201 is at an elevation above a top surface of the fin structure 113. In some embodiments, the top surface of the epitaxial portion 201 is below the bottom-most second semiconductor layer 1223. In some embodiments, the top surface of the epitaxial portion 201 connects to a sidewall of a bottom-most inner spacer 151.

Referring to FIGS. 9A and 9B, a mask layer 16 is formed in the region R2 after the formation of the inner spacers 151. The mask layer 16 is formed to prevent formation of a stepped structure 21 in undesired areas in subsequent processing for a purpose of adjustment of different functional sheets in the regions R1 and R2. Due to the formation of the mask layer 16, a number of the functional sheets in the region R1 is different from that in the region R2. In some embodiments, the mask layer 16 includes one or more high-k dielectric materials. In some embodiments, the mask layer 16 includes aluminum oxide.

In some embodiments, intermediate structures along the lines C-C′, E-E′, and G-G′ may be similar or identical to the intermediate structures along the line A-A′ at different stages prior to the formation of the mask layer 16. The steps and operations performed prior to the formation of the mask layer 16 described above are comprehensively performed over the substrate 11. Therefore, similarly, intermediate structures at different stages of the manufacturing method along the line I-I′ may be similar or identical to the intermediate structures along the line A-A′ at corresponding stages of the manufacturing method prior to the formation of the mask layer 16.

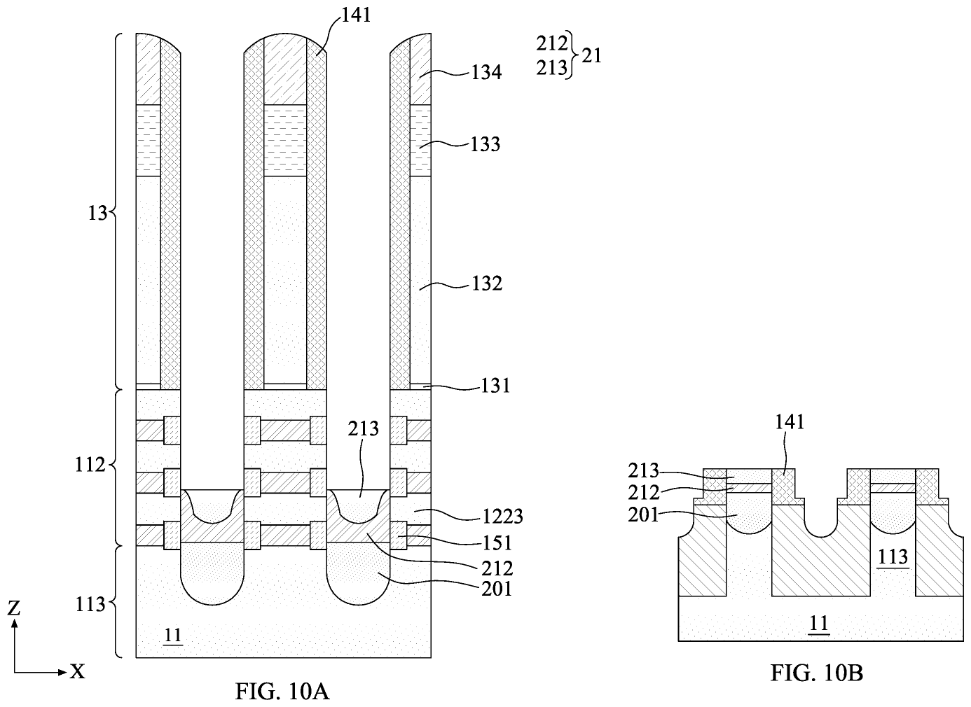

Referring to FIGS. 10A and 10B, the stepped structure 21 is formed in the region R1 over the epitaxial portion 201 between the stack structures 112 and between the sidewall spacers 141. In some embodiments, an epitaxial growth is performed, and parameters of the epitaxial growth are controlled to have a bottom-up growing direction. The stepped structure 21 can include different portions comprising different semiconductor materials. In some embodiments, the stepped structure 21 includes a lower portion 212 and an upper portion 213. In some embodiments, silicon and germanium are introduced at a beginning of the epitaxial growth to form the lower portion 212. In some embodiments, germanium is introduced for a certain duration from the beginning of the epitaxial growth, and is stopped when the lower portion 212 is formed. In some embodiments, silicon is introduced for an entire duration of the epitaxial growth. In accordance with a result of the epitaxial growth, an etching operation may be performed to adjust a profile of the stepped structure 21 or to remove undesired crystal formed on the sidewalls of the stack structures 112 during the epitaxial growth.

In alternative embodiments, a first epitaxial growth is performed to form the lower portion 212, and a second epitaxial growth is performed to form the upper portion 213. In some embodiments, a first etching operation is performed after the first epitaxial growth to adjust a profile of the lower portion 212. In some embodiments, a second etching operation is performed after the second epitaxial growth to adjust a profile of the upper portion 213. In some embodiments, the first epitaxial growth and the second epitaxial growth are performed in a same chamber. In some embodiments, the first etching operation and the second etching operation are performed in a same chamber. In some embodiments, the first and second epitaxial growths and the first and second etching operations are performed in a same chamber.

In some embodiments, the lower portion 212 contacts the epitaxial portion 201. In some embodiments, the lower portion 212 has a U-shaped configuration as shown in FIG. 10A. In some embodiments, the lower portion 212 contacts the sidewalls of adjacent stack structures 112. In some embodiments, the lower portion 212 contacts a bottom-most inner spacer 151 of an adjacent stack structure 112. In some embodiments, the lower portion 212 contacts a sidewall of a bottom-most second semiconductor layer 1223. In some embodiments, the upper portion 213 has a curved lower surface conformal to the lower portion 212. In some embodiments, the upper portion 213 is separated from the adjacent stack structure 112 by the lower portion 212. In some embodiments, a distance between the upper portion 213 and the adjacent stack structure 112 along the first direction is in a range of 1 to 4 nanometers (nm). A configuration of the stepped structure 21 is confined by the adjacent stack structures 112 and the adjacent sidewall spacers 141. In some embodiments, a top surface of the stepped structure 21 is substantially aligned with or below the top surface of the sidewall spacers 141. In some embodiments, the top surface of the stepped structure 21 includes the lower portion 212 and the upper portion 213. In some embodiments, lateral portions of the lower portion 212 are exposed through the upper portion 213.

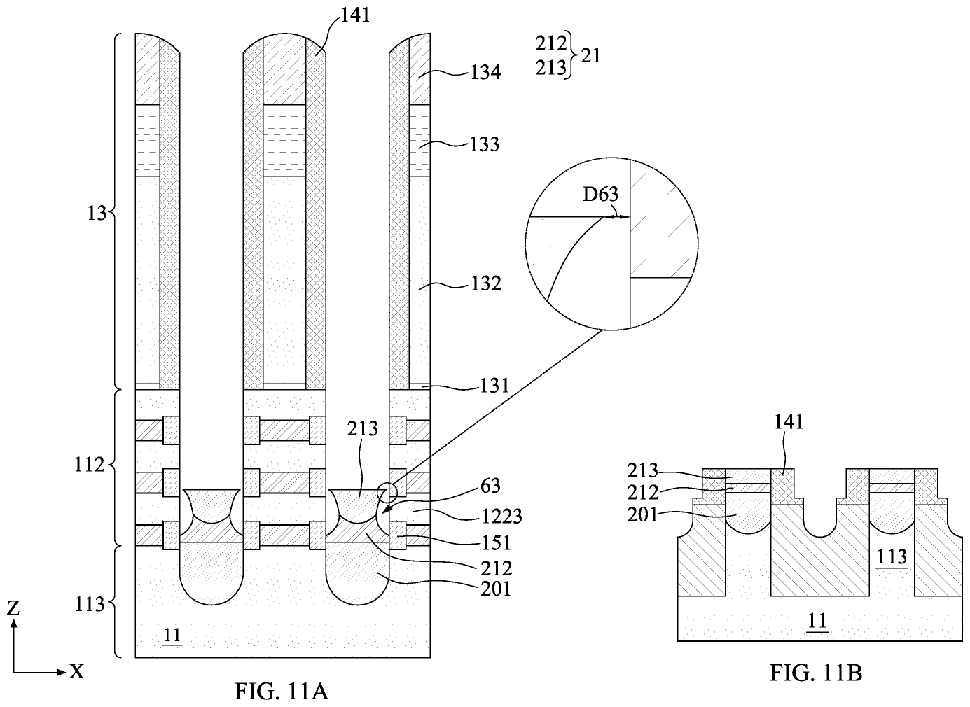

Referring to FIGS. 11A and 11B, the lateral portions of the lower portion 212 are removed to form recesses 63 between the upper portion 213 and the adjacent stack structures 112. In some embodiments, an etching operation is performed on the lower portion 212, thereby forming the recesses 63. The etching operation can be a dry etching, a wet etching, or a combination thereof. A width (measured along the first direction) of the recess 63 can vary along the second direction, depending on a profile of the recess 63. In other words, a distance between the upper portion 213 and the stack structure 112 can vary along the second direction. In some embodiments, a distance D63 between a corner at a top surface of the upper portion 213 and the stack structure 112 defines a shortest distance between the upper portion 213 and the stack structure 112. In some embodiments, the distance D63 is substantially equal to or greater than 0.8 nm. For a purpose of clarity, an enlarged view of a circled portion of the intermediate structure shown in FIG. 11A is provided.

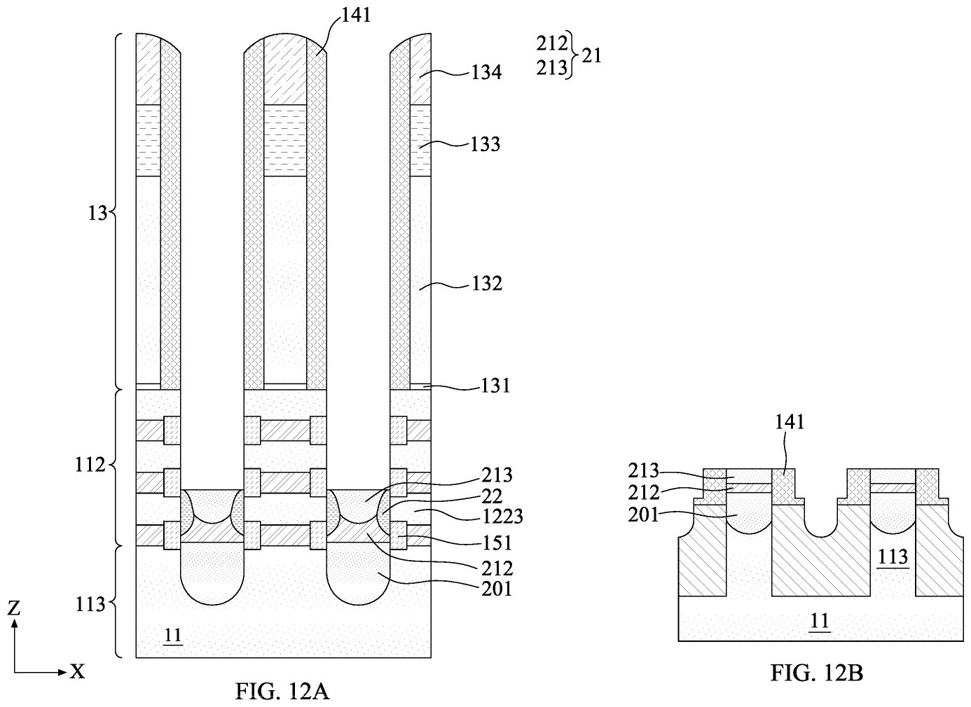

Referring to FIGS. 12A and 12B, a pair of sidewall spacers 22 are formed in the recesses 63 shown in FIG. 11A. The sidewall spacers 22 can be formed by a deposition of dielectric material followed by an etching operation. The dielectric material may be formed using a suitable process, such as ALD, PEALD, or a combination thereof. The etching operation can be a wet etching operation, a dry etching operation, or a combination thereof. In some embodiments, the dielectric material is formed comprehensively over the intermediate structure of FIGS. 11A and 11B in both the region R1 and the region R2. In some embodiments, the etching operation is performed comprehensively on the substrate 11. In some embodiments, the mask layer 16 covering the region R2 shown in FIGS. 9A and 9B serves to prevent formation of the stepped structure 21 in the region R2. The mask layer 16 covering the region R2 may be removed after the formation of the stepped structure 21. In some embodiments, the mask layer 16 is removed after the formation of the stepped structure 21 and prior to the removal of the lateral portions of the lower portion 212. In some embodiments, the mask layer 16 is removed after the formation of the sidewall spacers 22 and prior to formation of P-type S/D structures in subsequent processing.

Referring to FIGS. 13A, 13B, 13C and 13D, S/D structures 23 are formed in the regions R1 and R2. In some embodiments, the S/D structures 23 are P-type S/D structures. In some embodiments, a dielectric layer is formed prior to the formation of the S/D structures 23 to cover the N-type transistors, in which the dielectric layer is used as a mask to prevent formation of P-type S/D structures on the N-type transistors. In some embodiments, the transistors T2 and T3 shown in FIG. 1 are P-type transistors, and are exposed during the formation of the S/D structures 23. In some embodiments, the transistors T1 and T4 shown in FIG. 1 are N-type transistors, and are covered during the formation of the S/D structures 23. In some embodiments, the S/D structure 23 of the transistor T2 is formed on the upper portion 213 of the stepped structure 21. In some embodiments, the S/D structure 23 of the transistor T2 contacts the top surface of the upper portion 213 of the stepped structure 21. In some embodiments, the S/D structure 23 of the transistor T2 contacts the sidewall spacers 22. In some embodiments, as shown in FIG. 13B, a bottom surface of the S/D structure 23 of the transistor T2 is substantially aligned with the top surface of the sidewall spacers 141. In some embodiments, the S/D structure 23 of the transistor T3 is formed on the epitaxial portion 201. In some embodiments, the S/D structure 23 of the transistor T3 contacts a top surface of the epitaxial portion 201. In some embodiments, as shown in FIG. 14B, a bottom surface of the S/D structure 23 of the transistor T3 is below the top surface of the sidewall spacers 141.

As shown in FIGS. 13A, 13B, 13C and 13D, the bottom surfaces of the S/D structures 23 in different regions R1 and R2 are at different elevations, and the transistors T2 and T3 having a same type of conductivity but in different regions R1 and R2 can thereby have different numbers of functional nanosheets. As shown in FIG. 13A, the bottom-most second semiconductor layer 1223 is electrically isolated from the S/D structure 23 of the transistor T2. Therefore, the bottom-most second semiconductor layer 1223 of the transistor T2 becomes a dummy nanosheet due to a presence of the stepped structure 21 and the sidewall spacers 22. However, the S/D structure 23 of the transistor T3 shown in FIG. 13C electrically connects to the bottom-most second semiconductor layer 1223, and the bottom-most second semiconductor layer 1223 is a functional nanosheet of the transistor T3. Therefore, a number of functional nanosheets (i.e., a greater number of functional channels) of the transistor T3 in the absence of the stepped structure 21 is greater than a number of functional nanosheets of the transistor T2 in the presence of the stepped structure 21.

Referring to FIGS. 14A, 14B, 14C and 14D, S/D structures 25 are formed in the regions R1 and R2. In some embodiments, the S/D structures 23 are N-type S/D structures. In some embodiments, a dielectric layer is formed to cover the P-type transistors T2 and T3 prior to the formation of the S/D structures 25. In some embodiments, the transistors T1 and T4 shown in FIG. 1 are N-type transistors, and are exposed during the formation of the S/D structures 25. In some embodiments, the transistors T2 and T3 shown in FIG. 1 are P-type transistors, and are covered during the formation of the S/D structures 25. In some embodiments, the dielectric layer covering the N-type transistors during the formation of the S/D structures 23 is removed prior to the formation of the S/D structures 25.

As described above, the presence of a dielectric layer 24 below an S/D structure may not affect the strain of the S/D structure (or the effect of such presence on the strain is not significant and can be ignored) when the S/D structure 25 is an N-type S/D structure. In some embodiments, the dielectric layer 24 is formed after the formation of the S/D structures 23 and prior to the formation of the S/D structures 25 for a purpose of electrical isolation between a dummy nanosheet (e.g., the second semiconductor layer 1223 in the region R1) and the S/D structure 25. In some embodiments, the dielectric layer 24 is formed comprehensively over the substrate 11, and an etching operation is performed to remove portions of the dielectric layer 24. In some embodiments, the dielectric layer 24 remains on the stepped structures 21 of the transistor T1 (as shown in FIGS. 14A and 14B), on the epitaxial portion 201 of the transistor T4 (as shown in FIGS. 14C and 14D), and on top surfaces of the S/D structures 23 of the transistors T2 and T3 (as shown in FIGS. 2C, 2D, 2E and 2F). In some embodiments, the dielectric layer 24 can be omitted if the sidewall spacers 22 can provide sufficient electrical isolation. In some embodiments, if the dielectric layer 24 is absent, the formation of the S/D structures 25 can be performed prior to or after the formation of the S/D structures 23.

In some embodiments, the S/D structure 25 of the transistor T1 is formed over the dielectric layer 24 on the upper portion 213 of the stepped structure 21. In some embodiments, the S/D structure 25 of the transistor T1 contacts the dielectric layer 24. In some embodiments, the S/D structure 25 of the transistor T1 is separated from the stepped structure 21 or the sidewall spacers 22. In some embodiments, a bottom surface of the S/D structure 25 of the transistor T1 is above the top surface of the sidewall spacers 141. In some embodiments, the S/D structure 25 of the transistor T4 is formed over the dielectric layer 24 on the epitaxial portion 201. In some embodiments, the S/D structure 25 of the transistor T4 contacts the dielectric layer 24. In some embodiments, the S/D structure 25 of the transistor T4 is separated from the epitaxial portion 201 by the dielectric layer 24. In some embodiments, a bottom surface of the S/D structure 25 of the transistor T4 is below the top surface of the sidewall spacers 141.

A metal gate replacement procedure may be carried out after the formations of the S/D structures 23 and 25 to form the semiconductor structure 1 as shown in FIGS. 1 and 2A to 2H. The first semiconductor layers 121 are replaced by the gate structure 32 as shown in FIGS. 2A, 2C, 2E and 2G. The second semiconductor layers 122 may be referred to as nanosheets 122 after the metal gate replacement. In some embodiments, some of the nanosheets 122 adjacent to and laterally overlapped by the S/D structures 23 or 25 are referred to as functional nanosheets, and some of the nanosheets 122 adjacent to and laterally overlapped by the stepped structures 21 are referred to as dummy nanosheets.

The stepped structure 21 of the semiconductor structure 1 includes multiple portions with different concentrations of an element (e.g., germanium) selected from III-V groups. In other embodiments, the stepped structure 21 may be a monolithic structure with a uniform distribution of a semiconductor material.

In the description below, a semiconductor structure 2 with a monolithic epitaxial structure of the stepped structure 21 with a uniform distribution of a semiconductor material is provided. The semiconductor structure 2 may have a schematic top view identical to that of the semiconductor structure 1 shown in FIG. 1. Therefore, FIG. 1 is used to show the top view of the semiconductor structure 2 in the following description.

For a purpose of clarity and simplicity, reference numbers of elements with same or similar functions are repeated in different embodiments. However, such usage is not intended to limit the present disclosure to specific embodiments or specific elements. In addition, conditions or parameters illustrated in different embodiments can be combined or modified to form different combinations of embodiments as long as the parameters or conditions used are not in conflict.

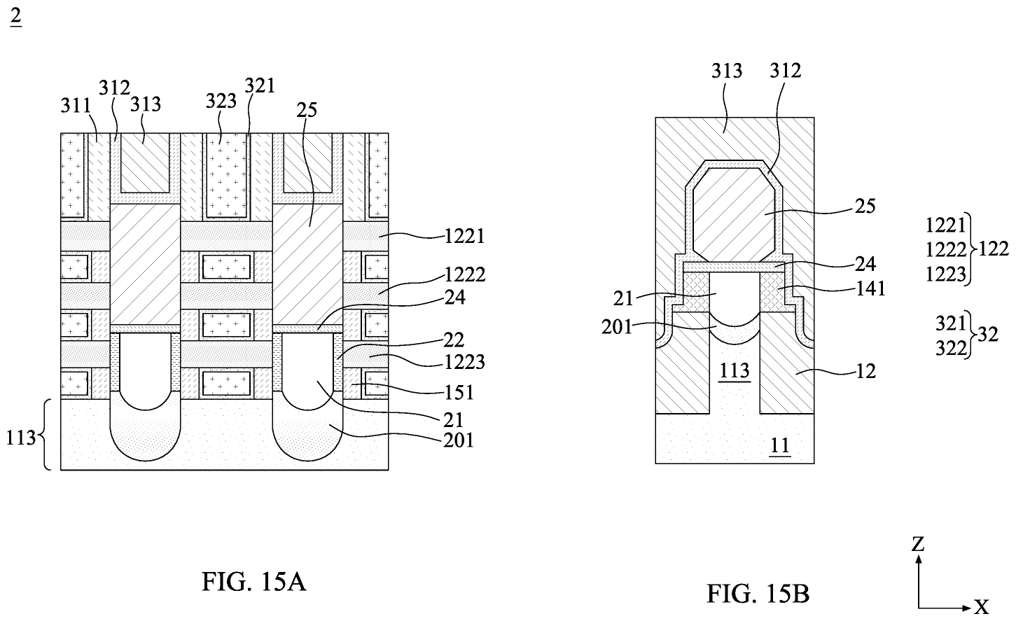

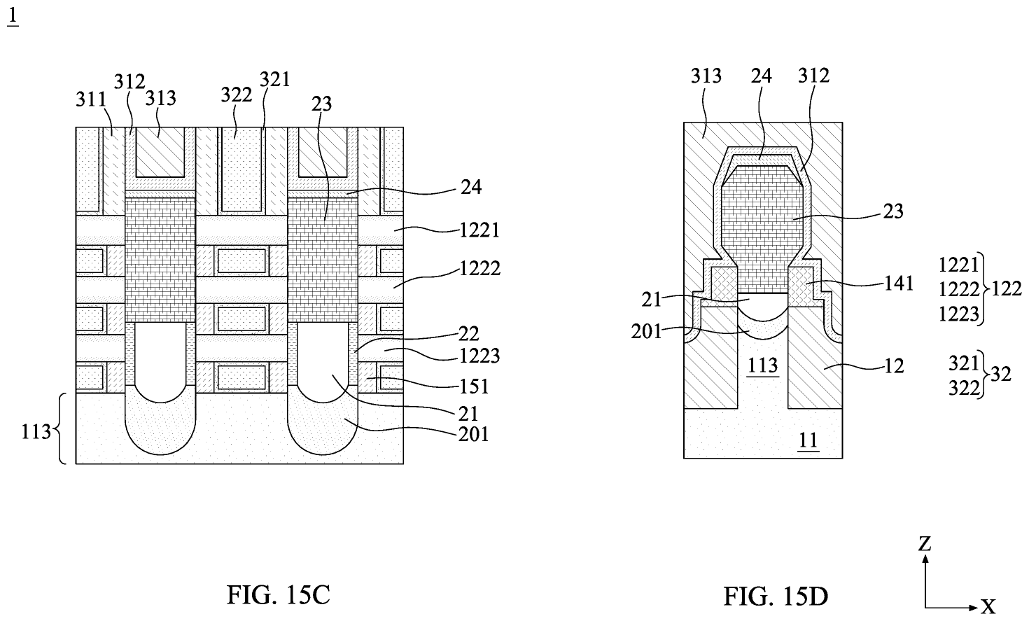

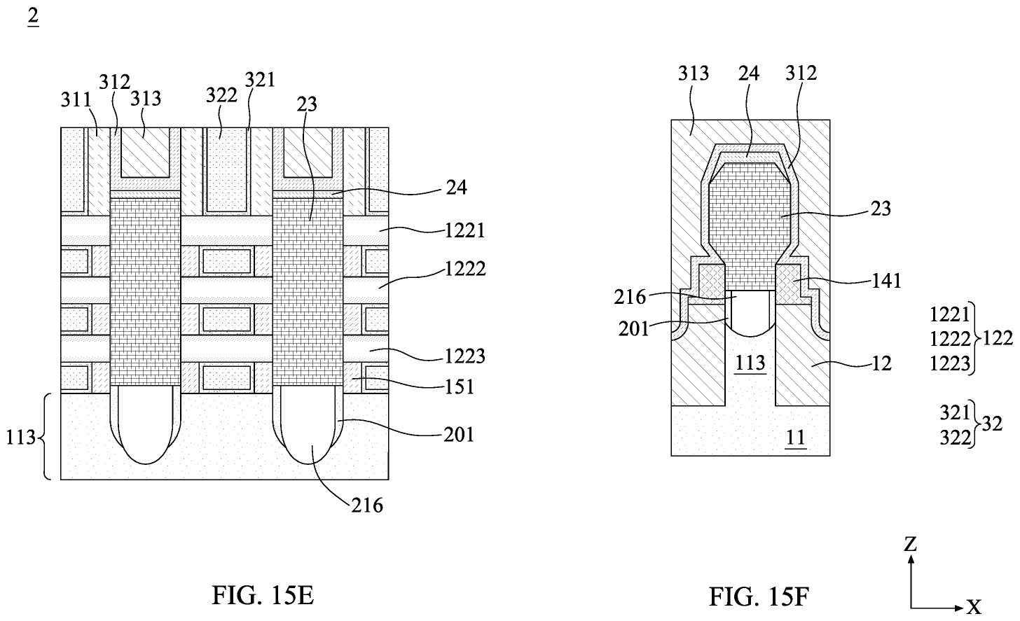

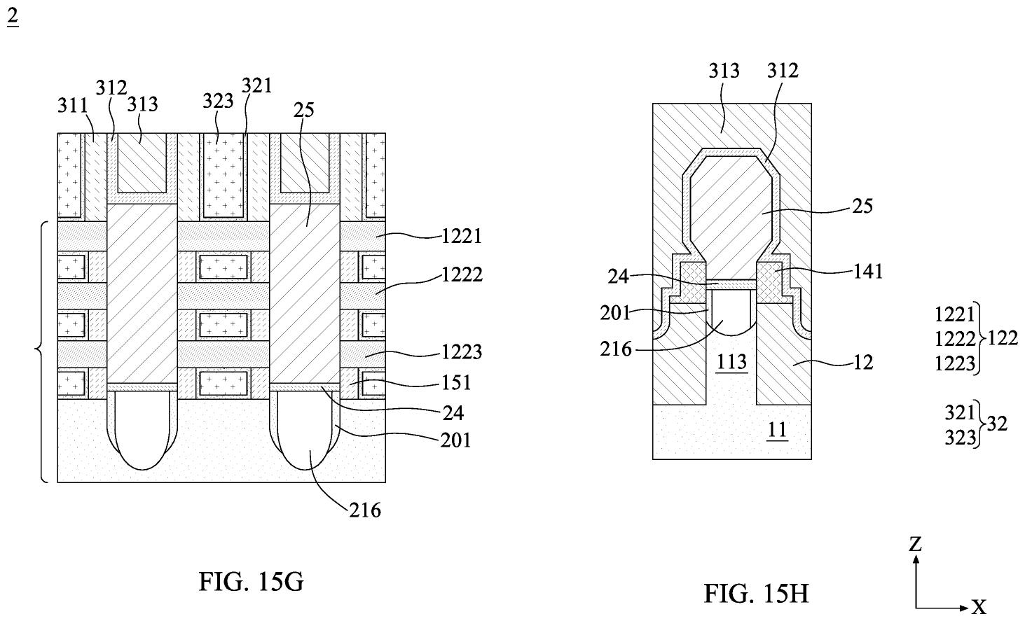

FIGS. 15A, 15B, 15C, 15D, 15E, 15F, 15G and 15H are schematic cross-sectional diagrams of the semiconductor structure 2 along the lines A-A′, B-B′, C-C′, D-D′, E-E′, F-F′, G-G′ and H-H′ respectively shown in FIG. 1 in accordance with other embodiments of the present disclosure. Transistors T1, T2, T3 and T4 shown in the figures are GAAFETs (e.g., nanosheet transistors) for exemplary illustration. However, the present disclosure is not limited thereto.

The semiconductor structure 2 can be similar to the semiconductor structure 1, but the stepped structure 21 of the semiconductor structure 2 is a monolithic structure and has a uniform concentration of a semiconductor material. For a purpose of brevity, only portions or manufacturing processes of the semiconductor structure 2 different from those of the semiconductor structure 1 are described below.

The stepped structure 21 of the semiconductor structure 2 may have a substantially straight sidewall facing a sidewall spacer 22. In some embodiments, the sidewall spacer 22 has a straight sidewall facing the stepped structure 21. In some embodiments, the stepped structure 21 includes a material same as that of the substrate 11. In some embodiments, a width of the sidewall spacer 22 measured along the first direction is in a range of 1 to 4 nm. In some embodiments, a height of the sidewall spacer 22 measured along the second direction is in a range of 10 to 20 nm.

As shown in FIGS. 15A and 15B, the stepped structure 21 of the transistor T1 is between the epitaxial portion 201 and the dielectric layer 24. In some embodiments, the stepped structure 21 of the transistor T1 contacts a top surface of the epitaxial portion 201 and a bottom surface of the dielectric layer 24. As shown in FIGS. 15C and 15D, the stepped structure 21 of the transistor T2 is between the epitaxial portion 201 and the S/D structure 23. In some embodiments, the stepped structure 21 of the transistor T2 contacts the top surface of the epitaxial portion 201 and a bottom surface of the S/D structure 23. In some embodiments, a bottom of the stepped structure 21 of the transistor T2 is below a top of the epitaxial portion 201. In some embodiments as shown in FIGS. 15A to 15D, in the region R1, a bottom of the stepped structure 21 is below a top of the epitaxial portion 201 and above a bottom of the epitaxial portion 201.

As shown in FIGS. 15E and 15F, the transistor T3 further includes an epitaxial portion 216 penetrating the epitaxial portion 201. In some embodiments, a top surface of the epitaxial portion 216 is substantially aligned with a top surface of the epitaxial portion 201. In some embodiments, the S/D structure 23 in the region R2 contacts the epitaxial portion 216. In some embodiments, a bottom surface of the S/D structure 23 contacts the top surface of the epitaxial portion 216. In some embodiments, a bottom of the S/D structure 23 in the region R2 is below a bottom of the epitaxial portion 201. As shown in FIGS. 15G and 15H, the transistor T4 also includes an epitaxial portion 216 penetrating the epitaxial portion 201. The epitaxial portion 216 of the transistor T4 can be similar to the epitaxial portion 216 of the transistor T3 but may contact the dielectric layer 24. In some embodiments, the S/D structure 25 in the region R2 is separated from the epitaxial portion 216 by the dielectric layer 24. In some embodiments, a bottom surface of the dielectric layer 24 contacts a top surface of the epitaxial portion 216 of the transistor T4.

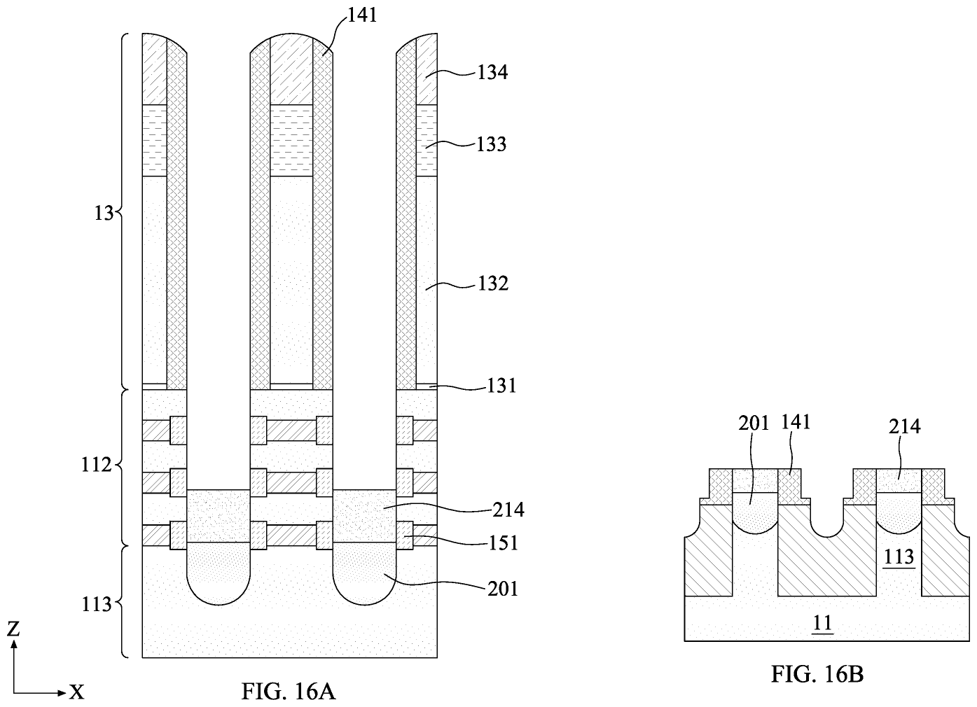

FIGS. 16A, 16B, 17A, 17B, 17C, 17D, 18A, 18B, 18C, 18D, 19A, 19B, 19C, 19D, 20A, 20B, 20C, 20D, 21A, 21B, 22A, 22B, 22C, 22D, 23A, 23B, 23C and 23D are schematic cross-sectional diagrams at different stages of a manufacturing method of the semiconductor structure 2 in accordance with some embodiments of the present disclosure.

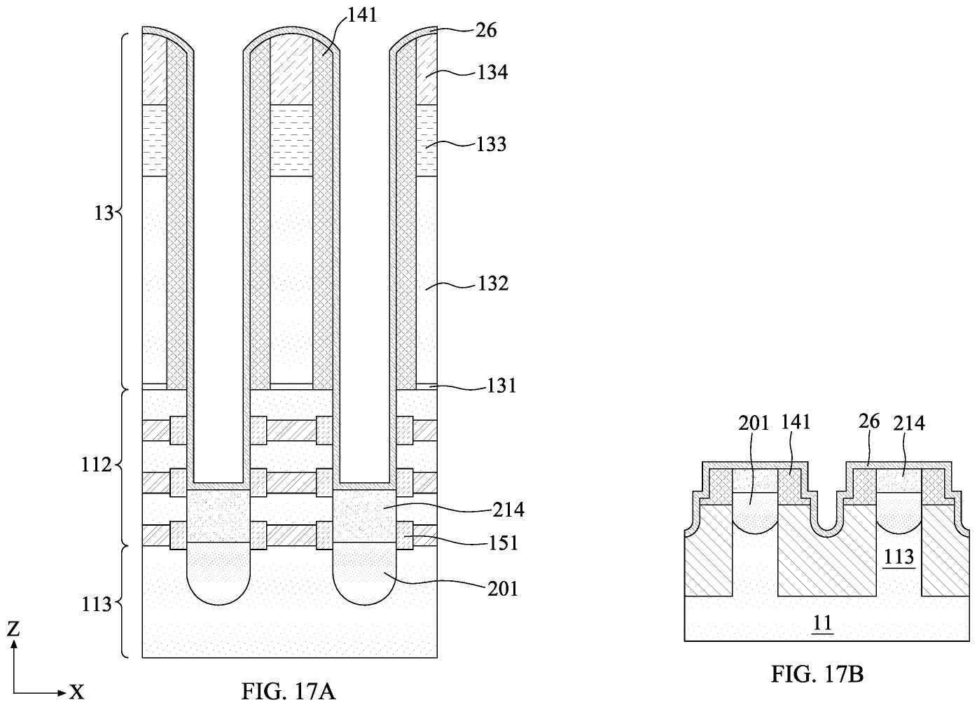

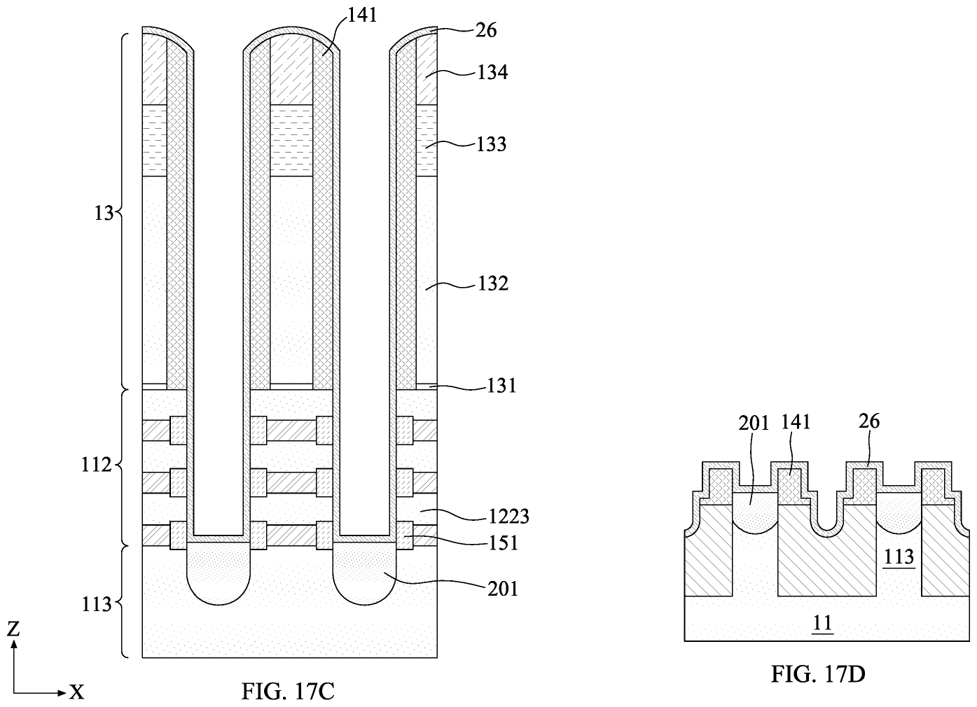

FIGS. 16A, 17A, 18A, 19A, 20A and 21A are schematic cross-sectional diagrams of the semiconductor structure 2 along the line A-A′ or C-C′ in FIG. 1 at different stages of a manufacturing method in accordance with some embodiments of the present disclosure. FIGS. 16B, 17B, 18B, 19B, 20B and 21B are schematic cross-sectional diagrams of the semiconductor structure 2 along a line I-I′ shown in FIG. 1 at different stages of the manufacturing method. FIGS. 17C, 18C, 19C and 20C are schematic cross-sectional diagrams of the semiconductor structure 2 along the line E-E′ or G-G′ at different stages of the manufacturing method. FIGS. 17D, 18D, 19D and 20D are schematic cross-sectional diagrams of the semiconductor structure 2 along the line J-J′ at different stages of the manufacturing method.

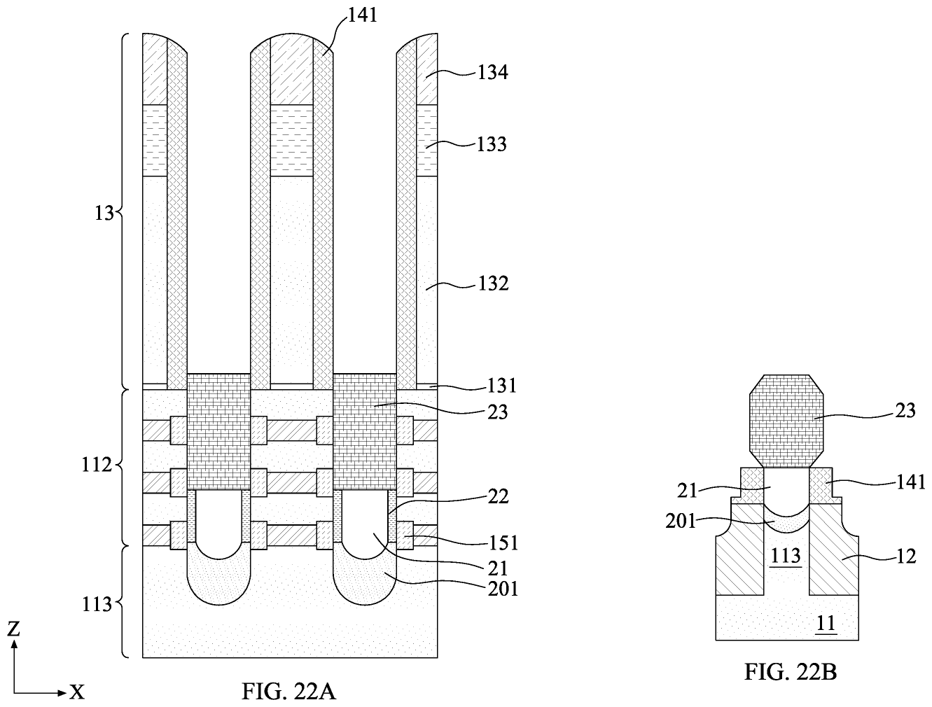

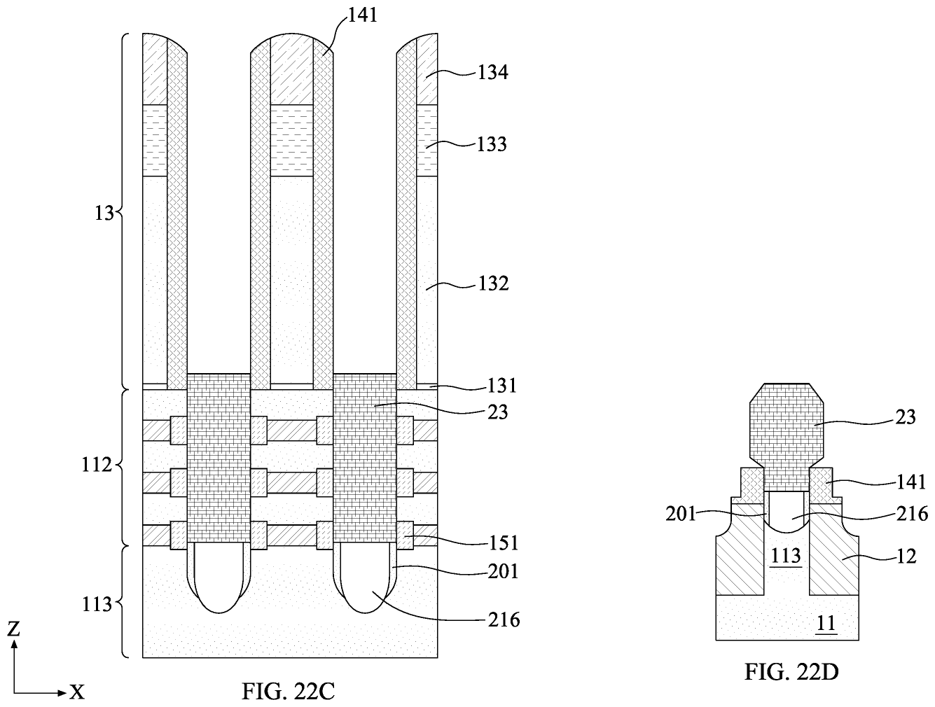

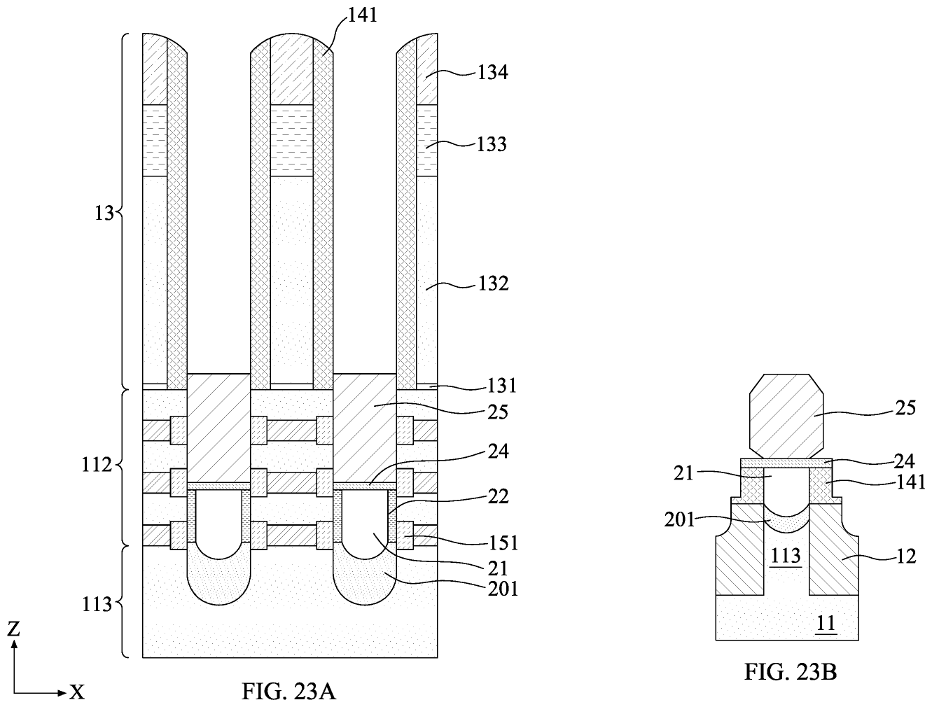

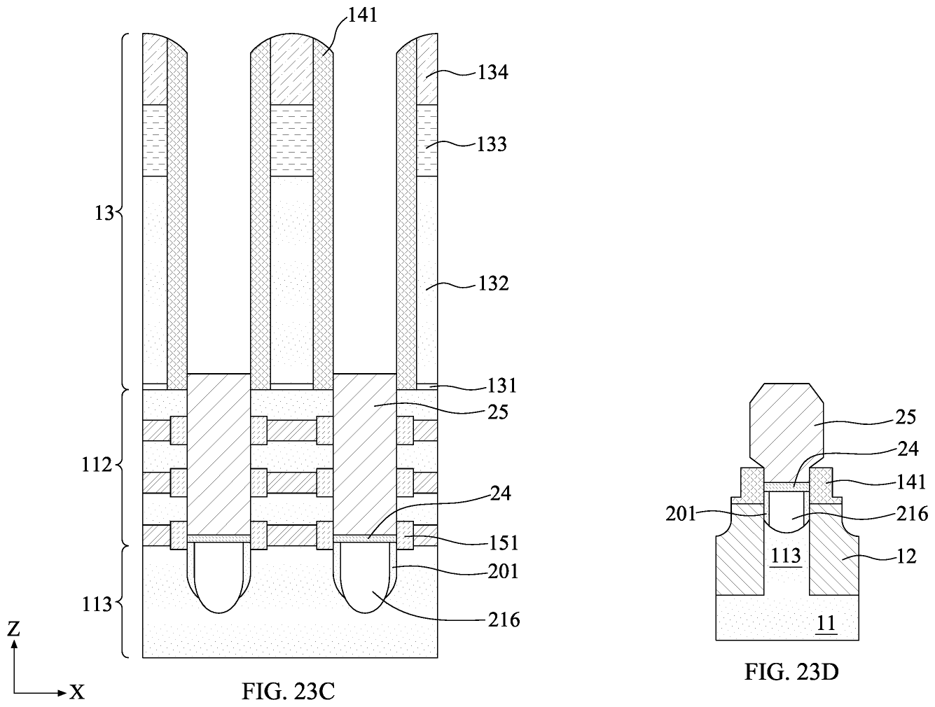

FIGS. 22A, 22B, 22C and 22D are schematic cross-sectional diagrams of the semiconductor structure 2 along the lines C-C′, D-D′, E-E′ and F-F′ respectively shown in FIG. 1 at a stage of a manufacturing method in accordance with some embodiments of the present disclosure. FIGS. 23A, 23B, 23C and 23D are schematic cross-sectional diagrams of the semiconductor structure 2 along the lines A-A′, B-B′, G-G′ and H-H′ respectively shown in FIG. 1 at a stage of a manufacturing method in accordance with some embodiments of the present disclosure.

Referring to FIGS. 16A and 16B, operations similar to those as depicted in FIGS. 3A to 10B are performed, but a sacrificial portion 214 is formed instead of the stepped structure 21. The method of forming the lower portion 212 can be applied to form the sacrificial portion 214, and repeated description is omitted herein. In some embodiments, the sacrificial portion 214 is formed directly on the epitaxial portion 201. In some embodiments, the sacrificial portion 214 contacts sidewalls of adjacent stack structures 112. In some embodiments, the sacrificial portion 214 contacts a bottom-most inner spacer 151 of an adjacent stack structure 112. In some embodiments, the sacrificial portion 214 contacts a sidewall of a bottom-most second semiconductor layer 1223. A configuration of the sacrificial portion 214 is confined by the adjacent stack structures 112 and the adjacent sidewall spacers 141. In some embodiments, a top surface of the sacrificial portion 214 is substantially aligned with or below a top surface of the sidewall spacers 141.

Referring to FIGS. 17A, 17B, 17C and 17D, a sacrificial layer 26 is formed over the intermediate structure shown in FIGS. 16A and 16B. The sacrificial layer 26 may be comprehensively formed in the regions R1 and R2. In some embodiments, a conformal deposition (e.g., ALD) is performed to form the sacrificial layer 26. In some embodiments, the sacrificial layer 26 includes one or more dielectric materials, such as nitride, oxynitride, or a combination thereof. In some embodiments, the mask layer 16 shown in FIGS. 9A and 9B for covering the region R2 prior to the formation of the sacrificial portion 214 is removed prior to the formation of the sacrificial layer 26. A thickness of the sacrificial layer 26 may define a width (or a thickness) of a sidewall spacer 22 formed in subsequent processing. In some embodiments, the thickness of the sacrificial layer 26 is in a range of 1 to 4 nm. In some embodiments, the thickness of the sacrificial layer 26 is consistent across the substrate 11. In some embodiments, the sacrificial layer 26 contacts the sacrificial portion 214 in the first region R1, and the sacrificial layer 26 contacts the epitaxial portion 201 in the second region R2.

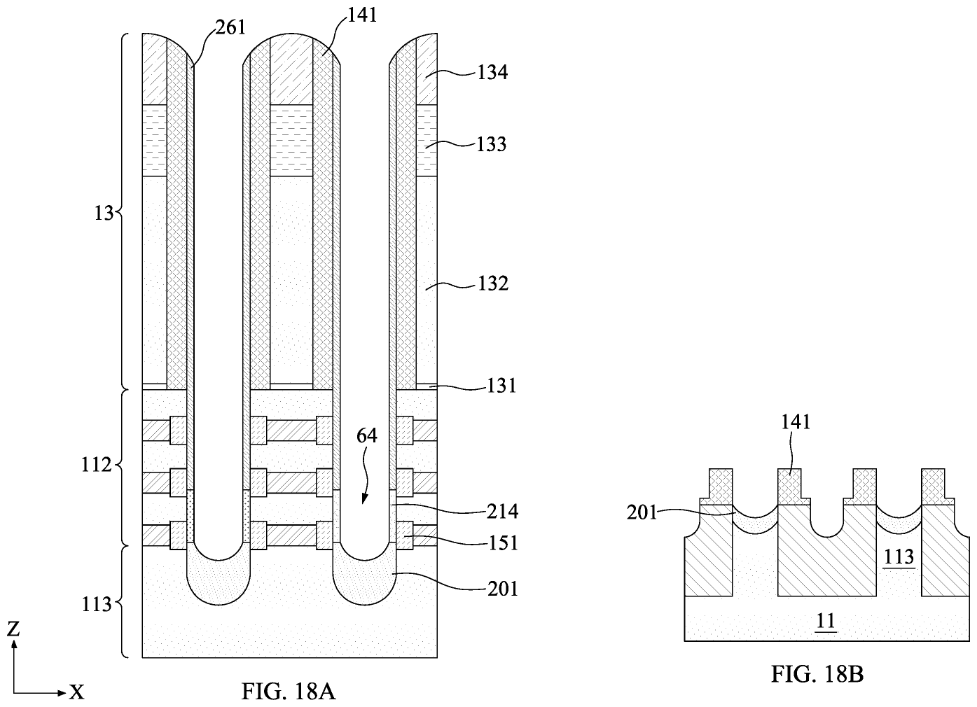

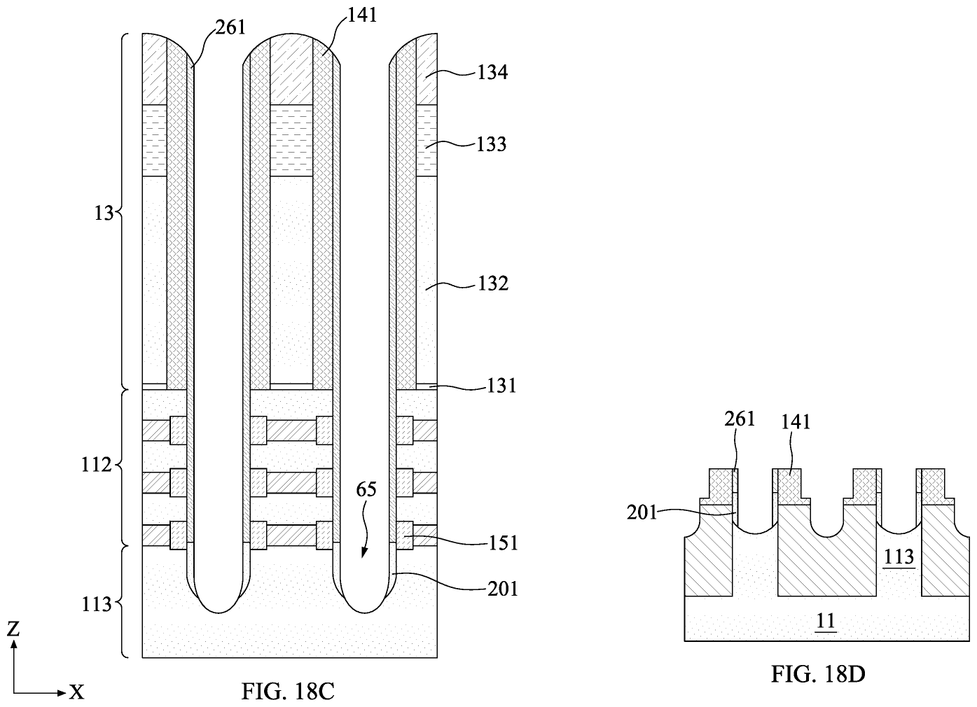

Referring to FIGS. 18A, 18B, 18C and 18D, an etching operation is performed. In some embodiments, the etching operation includes a dry etching operation. In some embodiments, the etching operation is non-selective. In some embodiments, portions of the sacrificial layer 26, portions of the sacrificial portion 214, portions of the epitaxial portion 201, and portions of the substrate 11 are concurrently removed.

In alternative embodiments, the etching operation includes multiple steps. In some embodiments, a spacer etching is performed to remove horizontal portions of the sacrificial layer 26 to form sacrificial spacers 261 on sidewalls of the dummy gate structures 13 and the sidewalls of the stack structures 112 above the sacrificial portion 214 in the first region R1 or above the epitaxial portion 201 in the second region R2, thereby forming the sacrificial spacers 261. In some embodiments, a step of a directional etching selective to the semiconductor materials of the sacrificial portion 214, the epitaxial portion 201 and the substrate 11 is performed. In some embodiments, the directional etching uses the dummy gate structures 13 and the sacrificial spacers 261 as a mask, thereby forming a trench 64 that penetrates each of the sacrificial spacers 261 and stops at a depth of the epitaxial portion 201 therebelow in the first region R1, and forming a trench 65 that penetrates the epitaxial portion 201 and stops at a depth of the fin structure 113 in the second region R2.

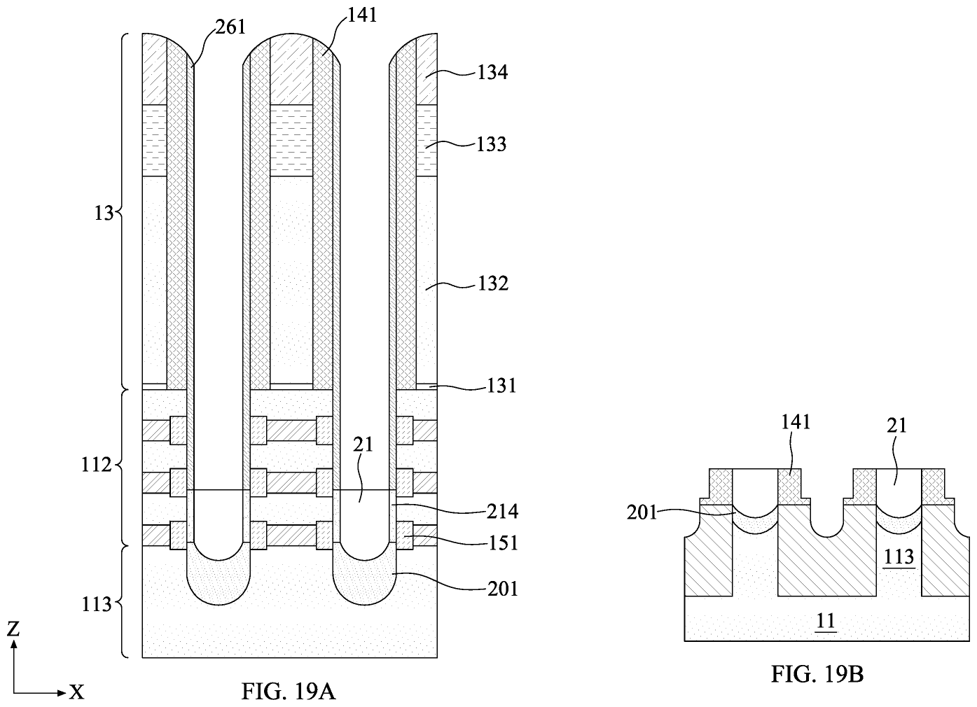

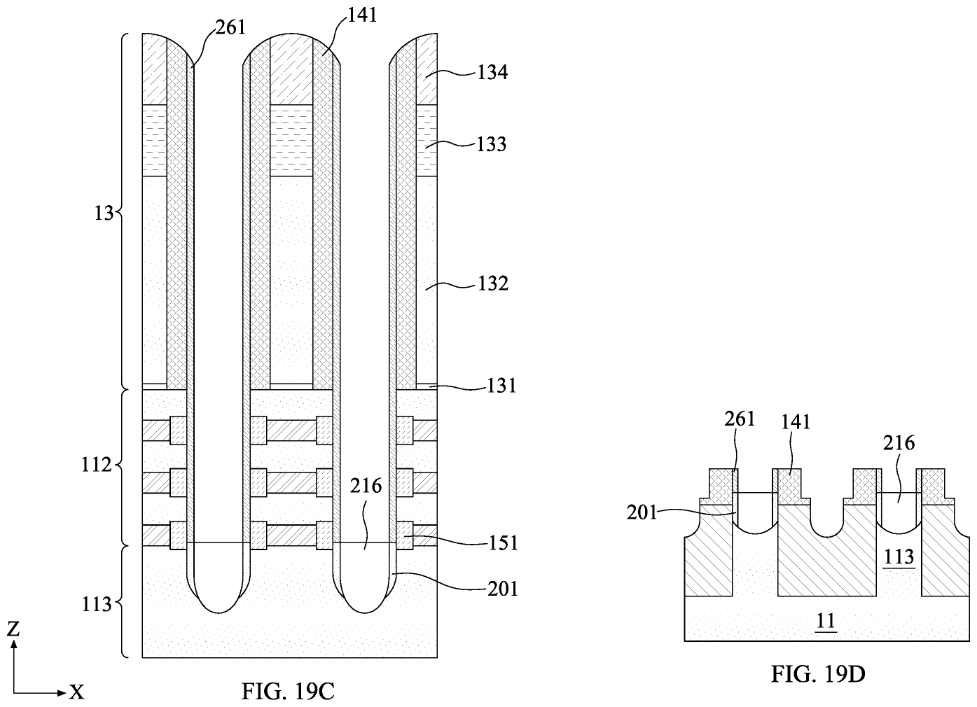

Referring to FIGS. 19A, 19B, 19C and 19D, an epitaxial growth is performed to form the stepped structure 21 and the epitaxial portion 216 in the first region R1 and the second region R2, respectively. The forming method of the upper portion 213 can be applied to form the stepped structure 21 and the epitaxial portion 216 of the semiconductor structure 2, and repeated description is omitted herein. In some embodiments, the stepped structure 21 includes polysilicon. In some embodiments, the stepped structure 21 includes a semiconductor material same as that of the substrate 11 or the epitaxial portion 201.

The stepped structure 21 is formed in the trench 64 shown in FIG. 18A and confined between remaining portions of the sacrificial portion 214 and the sidewall spacers 141. In some embodiments, a top surface of the stepped structure 21 is substantially aligned with a top surface of the sacrificial portion 214. In some embodiments, the top surface of the stepped structure 21 is substantially aligned with or below the top surface of the sidewall spacers 141. The epitaxial portion 216 is formed concurrently with the stepped structure 21. The epitaxial portion 216 is formed in the trench 65 shown in FIG. 18C and confined between remaining portions of the epitaxial portion 201.

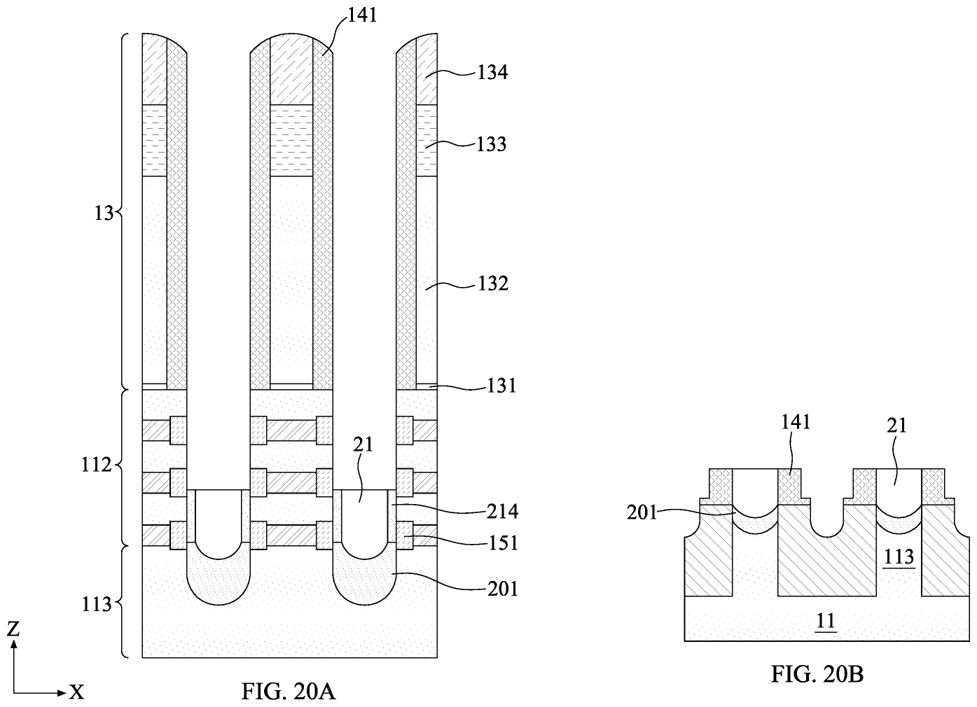

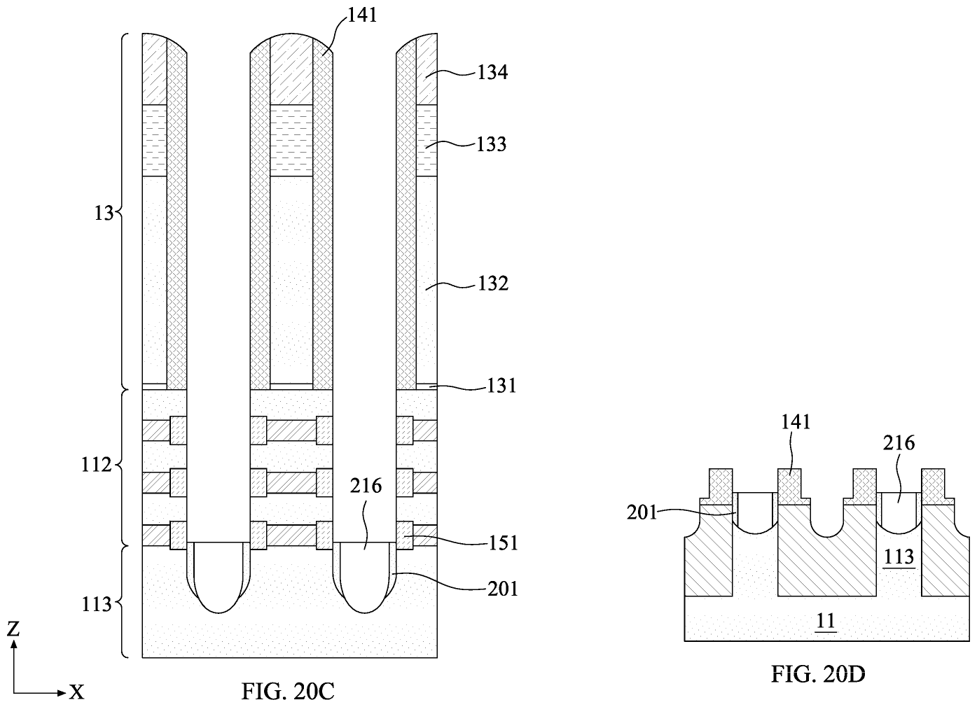

Referring to FIGS. 20A, 20B, 20C and 20D, the sacrificial spacers 261 are removed. In some embodiments, the remaining portions of the sacrificial portion 214 are exposed after the removal of the sacrificial spacers 261. In some embodiments, the remaining portions of the epitaxial portion 201 are exposed after the removal of the sacrificial spacers 261.

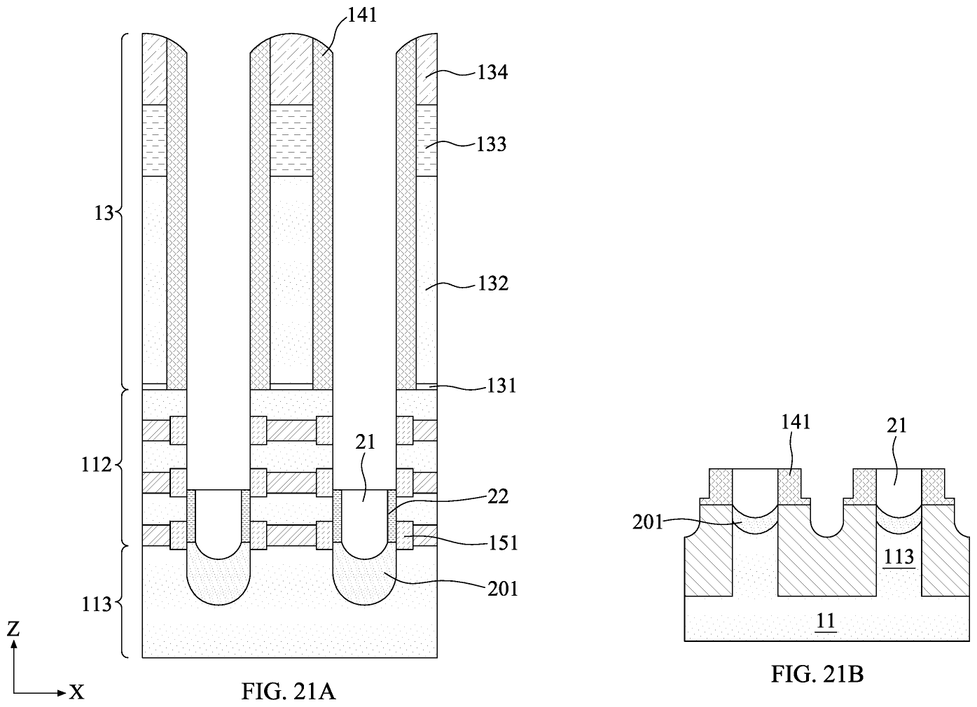

Referring to FIGS. 21A and 21B, the operations as depicted in FIGS. 11A, 11B, 12A and 12B are performed to form the sidewall spacers 22. As depicted in FIGS. 11A and 11B, an etching operation is performed on the remaining portions of the sacrificial portion 214 in the first region R1 to remove the remaining portions of the sacrificial portion 214 prior to the formation of the sidewall spacers 22. In some embodiments, the etching operation to remove the sacrificial portion 214 is selective to the semiconductor material (e.g., SiGe) of the sacrificial portion 214, and the second region R2 remains same as that shown in FIGS. 20C and 20D. The sidewall spacers 22 are thereby formed. In some embodiments, a top surface of the sidewall spacers 22 is substantially aligned with the top surface of the stepped structure 21.

Referring to FIGS. 22A, 22B, 22C and 22D, the operations as depicted in FIGS. 13A, 13B, 13C and 13D are performed to form the S/D structures 23. In some embodiments, the S/D structures 23 are formed directly over the stepped structures 21 in the first region R1. In some embodiments, the S/D structures 23 contact the sidewall spacers 22 in the first region R1. In some embodiments, the S/D structures 23 are formed directly over the epitaxial portions 216 in the second region R2. In some embodiments, the S/D structures 23 contact the remaining portions of the epitaxial portion 201 in the second region R2.

Referring to FIGS. 23A, 23B, 23C and 23D, the operations as depicted in FIGS. 14A, 14B, 14C and 14D are performed to form the S/D structures 25. In some embodiments, the S/D structure 25 in the first region R1 is formed directly over the dielectric layer 24 on the stepped structure 21 and the sidewall spacers 22. In some embodiments, the S/D structure 25 contacts the dielectric layer 24. In some embodiments, the S/D structure 25 in the first region R1 is separated from the stepped structure 21 or the sidewall spacers 22. In some embodiments, the S/D structure 25 in the second region R2 is formed directly over the dielectric layer 24 on the epitaxial portion 216. In some embodiments, the S/D structure 25 in the second region R2 contacts the dielectric layer 24. In some embodiments, the S/D structure 25 in the second region R2 is separated from the epitaxial portion 216 by the dielectric layer 24.

A metal gate replacement procedure may be carried out after the formations of the S/D structures 23 and 25 to form the semiconductor structure 2 as shown in FIG. 1 and FIGS. 15A to 15H. The first semiconductor layers 121 are replaced by the gate structure 32 as shown in FIGS. 15A, 15C, 15E and 15G. The second semiconductor layers 122 may be referred to as nanosheets 122 after the metal gate replacement. In some embodiments, some of the nanosheets 122 adjacent to and laterally overlapped by the S/D structures 23 or 25 are referred to as functional nanosheets, and some of the nanosheets 122 adjacent to and laterally overlapped by the stepped structures 21 are referred to as dummy nanosheets.

The above embodiments illustrate manufacturing methods and semiconductor structures thereof with equal channel lengths but different (functional) channel numbers in different regions for different performance requirements or different purposes. In cases of providing transistors with different channel lengths in different regions of a semiconductor structure, several issues, such as low product yield and difficulty and cost of formation of transistors with smaller channel lengths, may be encountered. By comparison, the proposed structures and methods discussed in the present disclosure can avoid the above issues that may be encountered, and more effective manufacturing integration can be achieved.

To conclude the processes of different embodiments as described above, a method 700 is provided.

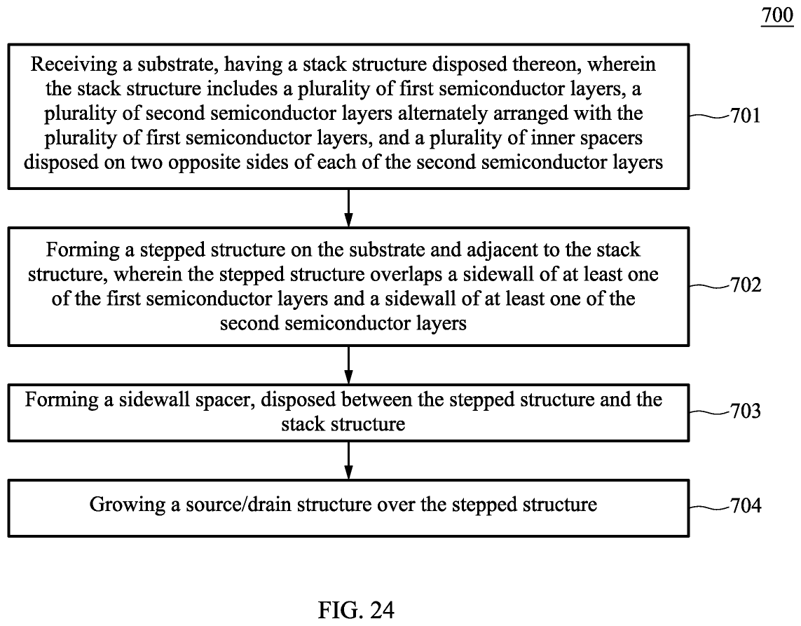

FIG. 24 is a flow diagram of the method 700 for manufacturing a semiconductor structure in accordance with some embodiments of the present disclosure. The method 700 includes a number of operations (701, 702, 703 and 704), and the description and illustration are not deemed as a limitation to the sequence of the operations. In the operation 701, a substrate having a stack structure disposed thereon is received, wherein the stack structure includes a plurality of first semiconductor layers, a plurality of second semiconductor layers alternately arranged with the plurality of first semiconductor layers, and a plurality of inner spacers disposed on two opposite sides of each of the second semiconductor layers. In the operation 702, a stepped structure is formed on the substrate and adjacent to the stack structure, wherein the stepped structure overlaps a sidewall of at least one of the first semiconductor layers and a sidewall of at least one of the second semiconductor layers. In the operation 703, a sidewall spacer is formed, wherein the sidewall spacer is disposed between the stepped structure and the stack structure. In the operation S704, a source/drain structure is grown over the stepped structure.

The operations of the method 700 can be rearranged or otherwise modified within the scope of the various aspects. In some embodiments, additional processes are provided before, during, and after the method 700, and some other processes are only briefly described herein. Thus, other implementations are possible within the scope of the various aspects described herein.

In accordance with some embodiments of the disclosure, a semiconductor structure is provided. The semiconductor structure includes a plurality of nanosheets, a gate structure, an S/D structure, a stepped structure, and a sidewall spacer. The plurality of nanosheets are disposed over a substrate, wherein the substrate extends along a first direction, and the nanosheets are arranged along a second direction substantially perpendicular to the first direction. The gate structure is disposed over the substrate, wherein the gate structure is disposed between and surrounding the nanosheets. The S/D structure is disposed adjacent to the gate structure and the plurality of nanosheets. The stepped structure is disposed below the S/D structure, wherein the stepped structure overlaps at least one of the nanosheets along the first direction. The sidewall spacer is disposed between the stepped structure and the at least one of the nanosheets.

In accordance with some embodiments of the disclosure, a semiconductor structure is provided. The semiconductor structure includes a first transistor and a second transistor. The first transistor comprises a plurality of first nanosheets, a first gate structure, and a first S/D structure. The plurality of first nanosheets are disposed over a substrate, wherein the substrate extends along a horizontal direction, and the first nanosheets are arranged along a vertical direction substantially perpendicular to the horizontal direction. The first gate structure is disposed over the substrate, wherein the first gate structure is disposed between and surrounding the first nanosheets. The first S/D structure is disposed over the substrate and adjacent to the first gate structure, wherein the first S/D structure overlaps a first number of the first nanosheets along the horizontal direction. The second transistor comprises a plurality of second nanosheets, a second gate structure, and a second S/D structure. The plurality of second nanosheets are disposed over the substrate and arranged along the vertical direction. The second gate structure is disposed over the substrate, wherein the second gate structure is disposed between and surrounding the second nanosheets. The second S/D structure is disposed over the substrate and adjacent to the second gate structure, wherein the second S/D structure overlaps a second number of the second nanosheets along the horizontal direction, and the second number is different from the first number.

In accordance with some embodiments of the disclosure, a method for manufacturing a semiconductor structure is provided. The method may include several operations. A substrate having a stack structure disposed thereon is received, wherein the stack structure includes a plurality of first semiconductor layers, a plurality of second semiconductor layers alternately arranged with the plurality of first semiconductor layers, and a plurality of inner spacers disposed on two opposite sides of each of the second semiconductor layers. A stepped structure is formed on the substrate and adjacent to the stack structure, wherein the stepped structure overlaps a sidewall of at least one of the first semiconductor layers and a sidewall of at least one of the second semiconductor layers. A sidewall spacer is formed, wherein the sidewall spacer is disposed between the stepped structure and the stack structure. A source/drain structure is grown over the stepped structure.

The foregoing outlines features of several embodiments so that those skilled in the art may better understand aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
a plurality of nanosheets, disposed over a substrate, wherein the substrate extends along a first direction, and the nanosheets are arranged along a second direction substantially perpendicular to the first direction;
a gate structure, disposed over the substrate, wherein the gate structure is disposed between and surrounding the nanosheets;
an S/D structure, disposed adjacent to the gate structure and the plurality of nanosheets;
a stepped structure, disposed below the S/D structure, wherein the stepped structure overlaps at least one of the nanosheets along the first direction; and
a sidewall spacer, disposed between the stepped structure and the at least one of the nanosheets.

2. The semiconductor structure of claim 1, wherein the stepped structure includes:
a first epitaxial portion, disposed below the S/D structure; and
a second epitaxial portion, disposed below the first epitaxial portion, wherein the second epitaxial portion and the first epitaxial portion include different semiconductor materials.

3. The semiconductor structure of claim 2, wherein the sidewall spacer contacts the first epitaxial portion and the second epitaxial portion.

4. The semiconductor structure of claim 2, wherein the sidewall spacer has a curved sidewall facing the stepped structure.

5. The semiconductor structure of claim 1, wherein the stepped structure is a monolithic epitaxial structure, and includes a semiconductor material same as that of the substrate.

6. The semiconductor structure of claim 5, wherein the sidewall spacer has a substantially straight sidewall facing the stepped structure.

7. The semiconductor structure of claim 1, wherein the S/D structure has an N-type conductivity, and the semiconductor structure further includes:
a dielectric layer, disposed between the stepped structure and the S/D structure.

8. The semiconductor structure of claim 1, wherein the S/D structure has a P-type conductivity, and the semiconductor structure further includes:
a dielectric layer, disposed over the S/D structure.

9. A semiconductor structure, comprising:
a first transistor, comprising:
a plurality of first nanosheets, disposed over a substrate, wherein the substrate extends along a horizontal direction, and the first nanosheets are arranged along a vertical direction substantially perpendicular to the horizontal direction;
a first gate structure, disposed over the substrate, wherein the first gate structure is disposed between and surrounds the first nanosheets; and
a first S/D structure, disposed over the substrate and adjacent to the first gate structure, wherein the first S/D structure overlaps a first number of the first nanosheets along the horizontal direction; and
a second transistor, comprising:
a plurality of second nanosheets, disposed over the substrate and arranged along the vertical direction;
a second gate structure, disposed over the substrate, wherein the second gate structure is disposed between and surrounds the second nanosheets; and
a second S/D structure, disposed over the substrate and adjacent to the second gate structure, wherein the second S/D structure overlaps a second number of the second nanosheets along the horizontal direction, and the second number is different from the first number.

10. The semiconductor structure of claim 9, wherein the first transistor further comprises:
a stepped structure, disposed below the first S/D structure; and
a sidewall spacer, disposed between the stepped structure and at least one of the first nanosheets below the first S/D structure.

11. The semiconductor structure of claim 10, wherein the stepped structure includes an upper portion and a lower portion, and germanium concentrations of the upper portion and the lower portion are different.

12. The semiconductor structure of claim 10, wherein the stepped structure is a monolithic structure, and the stepped structure includes a semiconductor material same as that of the substrate.

13. The semiconductor structure of claim 10, wherein the sidewall spacer has a width along the first direction in a range of 1 to 4 nanometers.

14. The semiconductor structure of claim 10, wherein the sidewall spacer has a length along the second direction in a range of 10 to 20 nanometers.

15. The semiconductor structure of claim 9, wherein a total number of the first nanosheets is same as a total number of the second nanosheets.

16. The semiconductor structure of claim 9, wherein
the first S/D structure includes a first source structure and a first drain structure, disposed on two opposite sides of the first nanosheets,
the second S/D structure includes a second source structure and a second drain structure, disposed on two opposite sides of the second nanosheets, and
a first distance between the first source structure and the first drain structure is substantially equal to a second distance between the second source structure and the second drain structure.

17. A method of manufacturing a semiconductor structure, comprising:
receiving a substrate, having a stack structure disposed thereon, wherein the stack structure includes a plurality of first semiconductor layers, a plurality of second semiconductor layers alternately arranged with the plurality of first semiconductor layers, and a plurality of inner spacers disposed on two opposite sides of each of the second semiconductor layers;
forming a stepped structure on the substrate and adjacent to the stack structure, wherein the stepped structure overlaps a sidewall of at least one of the first semiconductor layers and a sidewall of at least one of the second semiconductor layers;
forming a sidewall spacer, disposed between the stepped structure and the stack structure; and
growing a source/drain structure over the stepped structure.

18. The method of claim 17, wherein the stepped structure includes an upper portion and a lower portion having a germanium concentration greater than that of the upper portion, and the formation of the sidewall spacer includes:
etching the lower portion, thereby forming a recess between the upper portion and the stack structure;
depositing a dielectric layer over the substrate and in the recess; and
removing a portion of the dielectric layer, wherein a portion of the dielectric layer in the recess remains, and the sidewall spacer is thereby formed.

19. The method of claim 17, further comprising:
growing a first epitaxial structure, wherein the first epitaxial structure overlaps the sidewall of the at least one of the first semiconductor layers and the sidewall of the at least one of the second semiconductor layers;
forming a sacrificial spacer, disposed over the first epitaxial structure and on a sidewall of the stack structure;
etching the first epitaxial structure using the sacrificial spacer as a mask, wherein a portion of the first epitaxial structure covered by the sacrificial spacer remains;
growing a second epitaxial structure, thereby forming the stepped structure;
removing the remaining portion of the first epitaxial structure;
depositing a dielectric layer over the substrate and adjacent to the stepped structure; and
etching the dielectric layer, thereby forming the sidewall spacer.

20. The method of claim 18, wherein the first epitaxial structure includes a semiconductor material same as that of the first semiconductor layers, and the second epitaxial structure includes a semiconductor material same as that of the second semiconductor layers.
